(19) United States
(12) Patent Application Publication
(10) Pub. No.: US 2015/0014663 A1
(43) Pub. Date: Jan. 15, 2015

(54) ORGANIC LIGHT EMITTING DISPLAY APPARATUS AND THE METHOD FOR MANUFACTURING THE SAME

(71) Applicant: KOREA INSTITUTE OF SCIENCE AND TECHNOLOGY, Seoul (KR)

(72) Inventors: Soon Jong KWAK, Seoul (KR); Jae Ho JUN, Gyeonggi-do (KR); Myung Suk LEE, Gyeonggi-do (KR)

(21) Appl. No.: 14/329,313

(22) Filed: Jul. 11, 2014

(30) Foreign Application Priority Data
Jul. 11, 2013 (KR) 10-2013-0081788
Jul. 10, 2014 (KR) 10-2014-0087002

(51) Int. Cl. H01L 51/52; H01L 51/56; H01L 27/32

(52) U.S. Cl. CPC H01L 51/5256; H01L 27/3244; H01L 51/56
USPC 257/40; 438/28

(57) ABSTRACT

Provided is an organic light-emitting display apparatus including a hybrid protective film. The organic light-emitting display apparatus includes a substrate, a display unit disposed on the substrate and including an organic light-emitting device (OLED), and an encapsulation unit encapsulating the display unit and including the hybrid protective film. The hybrid protective film includes an inorganic part layer where carbon is removed, an organic part layer where carbon is contained in a predetermined amount, and a gradient part layer disposed between the inorganic part layer and the organic part layer and increasing an amount of carbon as being more contiguous to the organic part layer.

### RELATED APPLICATION

This application claims the benefit of Korean Patent Application No. 10-2013-0081788, filed on Jul. 11, 2013, and Korean Patent Application No. 10-2014-0087002, filed on Jul. 10, 2014, in the Korean Intellectual Property Office, the disclosures of which are incorporated herein in their entirety by reference.

### BACKGROUND

1. Field

One or more embodiments of the present invention relate to an organic light-emitting display apparatus and a method of manufacturing the same, and more particularly, to an organic light-emitting display apparatus that includes a hybrid protective film and a method of manufacturing the same.

2. Description of the Related Art

An organic light-emitting display apparatus is a self-emission display apparatus formed by using an organic light-emitting diode (OLED) which includes a hole injection electrode, an electron injection electrode, and an organic light-emitting layer disposed therebetween. The organic light-emitting display apparatus emits light when an exiton, generated when a hole injected from the hole injection electrode and an electron injected from the electron injection electrode combine in the organic light-emitting layer, drops from an exited state to a ground state.

Since the organic light-emitting display apparatus, which is a self-emission display apparatus, does not need an additional power source, the organic light-emitting display apparatus may be driven with a low voltage and may be formed as a light-weighted thin film. In addition, the organic light-emitting display apparatus provides high-quality characteristics such as wide angles, high contrast, and rapid responses. In this regard, the organic light-emitting display apparatus has gained a lot of attention as a next-generation display apparatus, and has been used in a variety of products such as a smartphone, a touch panel, a TV, and an aircraft display.

However, due to deterioration characteristics that the organic light-emitting display apparatus may have in response to external moisture or oxygen, an OLED needs to be encapsulated to prevent transmission of external moisture or oxygen.

In recent years, in order to manufacture a thin film and/or flexible organic light-emitting display apparatus, the organic light-emitting display apparatus concerning encapsulating an OLED uses thin film encapsulation (TFE) including a plurality of inorganic layers, a plurality of organic layers, or multiple layers of inorganic layers and organic layers that are alternately stacked. However, since the TFE is formed of a plurality of layers, the organic light-emitting display apparatus is thickened to improve moisture or oxygen blocking performance, and has additional manufacturing processes. Accordingly, the organic light-emitting display apparatus also has problems with increasing production costs.

### SUMMARY

One or more embodiments of the present invention include an organic light-emitting display apparatus including a hybrid protective film and a method of manufacturing the same.

Additional aspects will be set forth in part in the description which follows and, in part, will be apparent from the description, or may be learned by practice of the presented embodiments.

According to one or more embodiments of the present invention, an organic light-emitting display apparatus includes a substrate, a display unit disposed on the substrate and including an organic light-emitting diode (OLED), and an encapsulation unit encapsulating the display unit and including a hybrid protective film. The hybrid protective film includes an inorganic part layer where carbon is removed, an organic part layer where carbon is contained in a predetermined amount, and a gradient part layer disposed between the inorganic part layer and the organic part layer and increasing an amount of carbon as being more contiguous to the organic part layer.

The display unit may include a thin film transistor (TFT) on the substrate, a pixel electrode connected to the TFT, a pixel define layer exposing at least a part of the pixel electrode and defining an emission region, an organic light-emitting layer disposed on at least a part of the pixel electrode that is exposed by the pixel define layer, and a counter electrode disposed on the organic light-emitting layer and the pixel define layer.

The inorganic part layer and the gradient part layer may each have a predetermined thickness, but the organic part layer may be disposed thicker on the organic light-emitting layer than on the pixel define layer.

The encapsulation unit may further include an inorganic barrier layer that is disposed on the hybrid protective film and includes an inorganic material.

In some embodiments, the encapsulation unit may further include an organic inorganic composite layer disposed on the hybrid protective film. Here, the hybrid protective film may be formed by performing a plasma surface treatment on a layer that is formed of the same material as that of the organic-inorganic composite layer.

In some other embodiments, the encapsulation unit may further include an inorganic barrier layer that is disposed on the organic-inorganic composite layer and includes an inorganic material.

In some other embodiments, the encapsulation unit may further include an upper protective hybrid protective film that is disposed on the inorganic barrier layer and has a part layer structure that is the same as that of the hybrid protective film.

In some other embodiments, the encapsulation unit may further include an inorganic barrier layer that is disposed between the display unit and the hybrid protective film and includes an inorganic material.

In some other embodiments, the encapsulation unit may further include an organic-inorganic composite layer that is disposed between the display unit and the inorganic barrier layer. Here, the hybrid protective film may be formed by performing a plasma surface treatment on a layer that is formed of the same material as that of the organic-inorganic composite layer.

In some other embodiments, the encapsulation unit may further include an upper organic-inorganic composite layer that is disposed on the hybrid protective film and includes a material that is the same as that of the organic-inorganic composite layer, and an upper inorganic barrier layer that is disposed on the upper organic-inorganic composite layer and includes an inorganic material.

The hybrid protective film may have a skeleton of a network structure including —O—Si—O— linkages. Such a network structure contains silicon, oxygen, hydrogen, and carbon, and some silicon atoms may be directly bonded to carbon atoms that constitute a part of an organic functional group by covalent bond.

The network structure may further include at least one other element, and the other element may be at least one selected from alkali metal, alkali earth metal, transition metal, post-transition metal, metalloid, boron, and phosphorous. The other element may exist in an oxide form in an interstitial location inside the network structure, or may be linked to a silicon atom constituting the skeleton of the network structure by the covalent bond of other element-oxygen-silicon form.

Amounts of silicon and other element in the hybrid protective film may change within ±10 wt % in a thickness direction of the hybrid protective film.

The encapsulation unit may have a moisture transmission rate of 0.015 g/m²/day or less at a temperature of 37.8° C. and a relative humidity of 100%. The encapsulation unit may also have a light transmission rate of 85% or more with respect to light having a wavelength of 550 nm at a temperature of 25° C.

According to one or more embodiments of the present invention, an organic light-emitting display apparatus includes a flexible substrate, a display unit disposed on the flexible substrate and including an organic light-emitting device (OLED), and an encapsulation unit encapsulating an upper surface and side surfaces of the display unit. The encapsulation unit may include a hybrid protective film including an inorganic part layer where carbon is removed, an organic part layer where carbon is contained in a predetermined amount, and a gradient part layer disposed between the inorganic part layer and the organic part layer and increasing an amount of carbon as being more contiguous to the organic part layer, and additionally, at last one of an inorganic barrier layer including an inorganic material and an organic-inorganic composite layer including a material that is the same as that of the organic part layer. The encapsulation unit may have a moisture transmission rate of 0.009 g/m²/day or less at a temperature of 37.8° C. and a relative humidity of 100%.

According to one or more embodiments of the present invention, a method of manufacturing an organic light-emitting display apparatus includes: forming a display unit including an organic light-emitting device (OLED) on a substrate; preparing an organic-inorganic composite coating solution by performing sol-gel hydrolysis and condensation on an organic-inorganic mixed solution including an organic material and an inorganic material; forming an organic-inorganic composite layer by coating a surface of the display unit with the organic-inorganic composite coating solution to encapsulate the display unit; and treating the surface of the organic-inorganic composite layer with plasma of reactive gas to form a hybrid protective film including an inorganic part layer where carbon is removed, an organic part layer where carbon is contained in a predetermined amount, and a gradient part layer disposed between the inorganic part layer and the organic part layer and increasing an amount of carbon as being more contiguous to the organic part layer. Here, the plasma treatment may be performed until the inorganic part layer is formed inside the hybrid protective film to a predetermined thickness.

The organic-inorganic mixed solution may include at least one organosilane represented by Formula 1 below, water, and optionally, at least one silicate ester represented by Formula 2 below:

A¹ₗA²ₘA³ₙSi(OE¹)ₚ(OE²)_{q}(OE³)ᵣ [Formula 1]

Si(OG¹)_{α}(OG²)_{β}(OG³)_{γ}(OG⁴)_{δ} [Formula 2]

In Formula 1, A¹, A², and A³ are each independently a C₁-C₂₀ alkyl group, a C₁-C₂₀ fluoroalkyl group, a C₆-C₂₀ aryl group, a vinyl group, an acryl group, a methacryl group, or an epoxy group, l, m, and n are each independently 0 or an integer satisfying the equation of 1≦l+m+n≦3, E¹, E², E³ are each independently a C₃-C₁₀ alkyl group, a C₁-C₁₀ fluoroalkyl group, a C₆-C₂₀ aryl group, a C₁-C₂₀ alkyloxyalkyl group, a C₁-C₂₀ fluoroalkyloxyalkyl group, a C₁-C₂₀ alkyloxyaryl group, a C₆-C₂₀ aryloxyalkyl group, or a C₆-C₂₀ aryloxyaryl group, and p, q, and r are each independently 0 or an integer of 1 to 3 satisfying the equation of 1≦p+q+r≦3 and l+m+n+p+q+r=4.

In Formula 2, G¹, G², G³, and G⁴ are each independently a C₁-C₁₀ alkyl group, a C₁-C₁₀ fluoroalkyl group a C₆-C₂₀ aryl group, a C₁-C₂₀ alkyloxyalkyl group, a C₁-C₂₀ fluoroalkyloxyalkyl group, a C₁-C₂₀ alkyloxyaryl group, a C₆-C₂₀ aryloxyalkyl group, or a C₆-C₂₀ aryloxyaryl group, and α, β, γ, and δ are each independently 0 or an integer of 1 to 4 satisfying the equation of α+β+γ+δ=4.

The organic-inorganic mixed solution may further include at least one oxide precursor, and the oxide precursor may include at least one other element selected from alkali metal, alkali earth metal, transition metal, post-transition metal, metalloid, boron, and phosphorous. In addition, the oxide precursor may be capable of forming an oxide of the other element and oxygen.

The organic light-emitting display apparatus may further include at least one of the organic-inorganic composite layer and the inorganic barrier layer including an inorganic material, on top of the hybrid protective film.

The organic light-emitting display apparatus may further include at least one of the organic-inorganic composite layer and the inorganic barrier layer including an inorganic material between the display unit and the hybrid protective film.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic cross-sectional view of an organic light-emitting display apparatus according to one or more embodiments of the present invention;

FIG. 2 is a schematic cross-sectional view of a pixel region in the organic light-emitting display apparatus according to an embodiment of the present invention;

FIG. 3 is a schematic cross-sectional view of a pixel region in the organic light-emitting display apparatus according to another embodiment of the present invention;

FIG. 4 is a schematic cross-sectional view of a pixel region in the organic light-emitting display apparatus according to another embodiment of the present invention;

FIG. 5 is a schematic cross-sectional view of a pixel region in the organic light-emitting display apparatus according to another embodiment of the present invention;

FIG. 6 is a schematic cross-sectional view of a pixel region in the organic light-emitting display apparatus according to another embodiment of the present invention;

FIG. 7 is a schematic cross-sectional view of a pixel region in the organic light-emitting display apparatus according to another embodiment of the present invention; and

FIG. 8 is a schematic cross-sectional view of a pixel region in the organic light-emitting display apparatus according to another embodiment of the present invention.

### DETAILED DESCRIPTION

Hereinafter, the present invention will be described more fully with reference to the accompanying drawings, in which exemplary embodiments of the invention are shown. These embodiments are provided so that this disclosure will fully convey the concept of the invention to one of ordinary skill in the art. The invention may, however, be embodied in many different forms and should not be construed as being limited to the embodiments set forth herein. In other words, it is to be appreciated that all changes, equivalents, and substitutes that do not depart from the spirit and technical scope of the present invention are encompassed in the present invention.

The present invention will be described in detail by explaining exemplary embodiments of the invention with reference to the attached drawings. Similar reference numerals in the drawings denote similar elements. Sizes of components in the drawings may be exaggerated for convenience of explanation. In other words, since sizes and thicknesses of components in the drawings are arbitrarily illustrated for convenience of explanation, the following embodiments are not limited thereto.

The terms used in the present specification are merely used to describe particular embodiments, and are not intended to limit the present invention. An expression used in the singular encompasses the expression of the plural, unless it has a clearly different meaning in the context. It will be further understood that the terms “comprises” and/or “comprising” used herein specify the presence of stated features or components, but do not preclude the presence or addition of one or more other features or components. It will be understood that although the terms “first”, “second”, etc. may be used herein to describe various components, these components should not be limited by these terms. These components are only used to distinguish one component from another. Here, in the case where a first feature is described to be linked, coupled, or connected with a second feature, the case is not intended to preclude the possibility that a third feature may be disposed between the first feature and the second feature. In addition, in the case where a first element is disposed on a second element, the case is not intended to preclude the possibility that a third element may be disposed between the first element and the second element. However, in the case where a first element is directly disposed on a second element, that case is intended to exclude the possibility that a third element may be disposed between the first element and the second element.

Unless defined otherwise, all terms used herein including technical or scientific terms have the same meanings as those generally understood by one of ordinary skill in the art. The terms as those defined in generally used dictionaries are construed to have meanings matching those in the context of related technology and, unless clearly defined otherwise, are not construed to be ideally or excessively formal.

As used herein, the term “and/or” includes any and all combinations of one or more of the associated listed items. Expressions such as “at least one of,” when preceding a list of elements, modify the entire list of elements and do not modify the individual elements of the list.

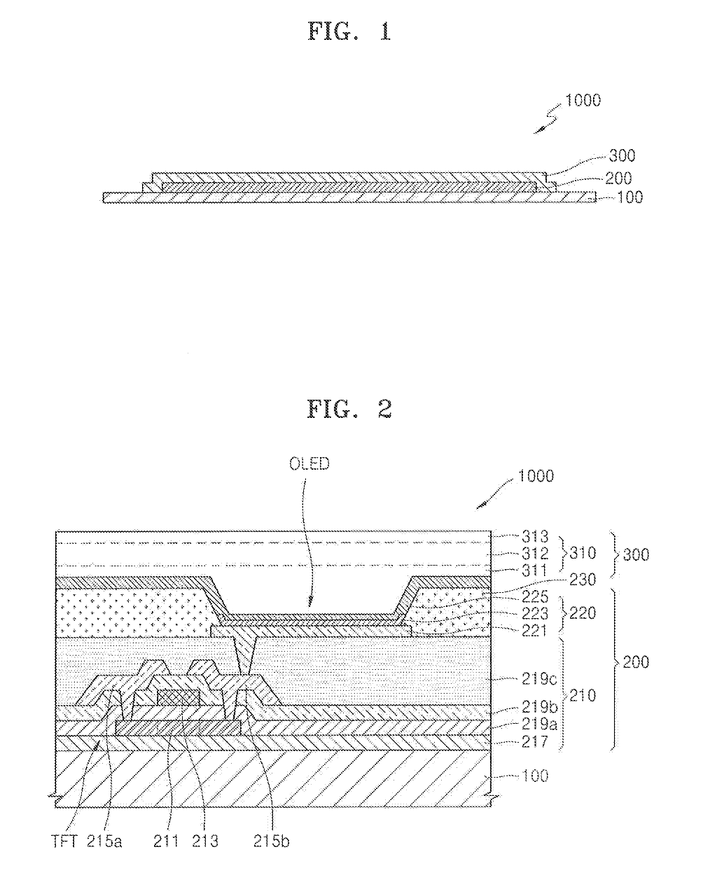

FIG. 1 is a schematic cross-sectional view of an organic light-emitting display apparatus according to one or more embodiments of the present invention.

Referring to FIG. 1, an organic light-emitting display apparatus 1000 according to one or more embodiments of the present invention includes a substrate 100, a display unit 200 disposed on one surface of the substrate 100, and an encapsulation unit 300 encapsulating the display unit 200.

The display unit 200 may include an organic light-emitting device (OLED) and a thin film transistor (TFT) for driving the OLED.

The encapsulation unit 300 may include a hybrid protective film. The hybrid protective film may include an inorganic part layer where carbon is removed, an organic part layer where carbon is contained in a predetermined amount, and a gradient part layer disposed between the inorganic part layer and the organic part layer and increasing an amount of carbon as being more contiguous to the organic part layer. When the encapsulation unit 300 including the hybrid protective film is formed on the display unit 200, the display unit 200 may be protected from moisture and oxygen in the ambient air.

FIG. 2 is a schematic cross-sectional view of a pixel region in the organic light-emitting display apparatus according to an embodiment of the present invention.

Referring to FIG. 2, the organic light-emitting display apparatus 1000 may include the substrate 100, the display unit 200, and the encapsulation unit 300.

The substrate 100 may be a flexible substrate. The substrate 100 may be formed of a plastic material having excellent heat resistance and durability, such as polyimide (PI), polyethylene terephthalate (PET), polyethylene naphtalate (PEN), polycarbonate (PC), polyarylate (PAR), polyetherimide (PEI), polyethersulphone (PES), and Fiber Reinforced Plastics. However, the present invention is not limited thereto, and the substrate 100 may be formed of various materials having flexible characteristics, such as metal foil or thin glass. In addition, the substrate 100 may be a rigid substrate and may be formed of a glass material having SiO₂ as a major component.

In the case of a bottom emission type organic light-emitting display apparatus in which an image is implemented in a direction toward the substrate 100, the substrate 100 is necessarily formed of a transparent material. However, in the case of a top emission type organic light-emitting display apparatus in which an image is implemented in a direction opposite to the substrate 100, the substrate 100 is not necessarily formed of a transparent material, and instead, may be formed of a metal material. When the substrate 100 is formed of a metal material, the substrate 100 may include at least one selected from the group consisting of carbon, iron, chromium, manganese, nickel, titanium, molybdenum, and stainless steel (SUS), but is not limited thereto.

The display unit 200 may be disposed on an upper surface of the substrate 100. The term “display unit 200” used herein refers to an array of an OLED and a thin film transistor (TFT) for driving the OLED, and also refers to both an image displaying part and a driving part for displaying an image.

When viewed on a planar view, the display unit 200 may include a plurality of pixels that are arranged in a matrix form. Each of the plurality of pixels includes an OLED and an electronic device that is electrically connected to the OLED. The electronic device may include at least two TFTs, each of which includes a driving TFT and a switching TFT, and a storage capacitor. In this regard, electronic signals are transmitted from an external driving unit to the display unit 200 by wires that are electronically connected to the electronic device, thereby driving the OLED. Such an array of the electronic device electronically connected to the OLED is referred to as a TFT array.

The display unit 200 may include a device/wiring layer 210 including a TFT array, and an OLED layer 220 including an OLED array.

The device/wiring layer 210 may include a driving TFT for driving an OLED, a switching TFT (not shown), a capacitor (not shown), wires (not shown) connected to these TFTs or the capacitor. FIG. 2 only illustrates an OLED and a driving TFT for driving the OLED. However, such illustration is merely for convenience of explanation, and is not intended to limit the present invention. That is, it is obvious for one of ordinary skill in the art to understand that the present invention may further include a plurality of TFTs, storage capacitors, and various wires.

On an upper surface of the substrate 100, a buffer layer 217 may be disposed to provide planarity and to block permeation of impurities. The buffer layer 217 may be formed of an inorganic material, such as silicon oxide, silicon nitride, silicon nitroxide, aluminum oxide, aluminum nitride, titanium oxide, or titanium nitride, or an organic material, such as PI, polyester, or acryl. In addition, the buffer layer 217 may be formed by stacking a plurality of materials that are selected from the materials listed above. When an inorganic material is included in the buffer layer 217, the buffer layer 217 may be disposed on the substance 100 by using various deposition methods, such as plasma enhanced chemical vapor deposition (PECVD), an atmospheric pressure CVD (APCVD), and low pressure CVD (LPCVD). For example, the formation of the buffer layer 217 may be omitted.

An active layer 211 may be arranged within a predetermined region on the buffer layer 217. An inorganic semiconductor, such as silicon or an oxide semiconductor, or an organic semiconductor may be formed over the entire surface of the flexible substrate 100 including the buffer layer 217, and then, may be patterned into the active layer 211 on the buffer layer 217 by using a photolithographic process and an etching process.

When the active layer 211 is formed of a silicon material, an amorphous silicon layer may be formed over the entire surface of the buffer layer 217, and crystallized, and thus, the active layer 211 formed of a polysilicon layer may be formed. The amorphous silicon layer may be crystallized by using a variety of methods, such as a rapid thermal annealing (RTA) method, a solid phase crystallization (SPC) method, an excimer laser annealing (ELA) method, a metal induced crystallization (MIC) method, a metal induced lateral crystallization (MILC) method, and a sequential lateral solidification (SLS) method. The polysilicon layer may be patterned into the active layer 211 by using a photolithographic process and an etching process. Some regions of the active layer 211 may be doped with impurities, such as boron (B) ions or phosphorous (P) ions, so that the active layer 211 including a source region, a drain region, and a channel region that is identifiable between the source region and the drain region may be formed.

In some other embodiments, the amorphous silicon layer may be patterned first, and then, the patterned amorphous silicon layer may be crystallized to form polysilicon patterns.

A first insulation layer 219a may be disposed on the active layer 211. The first insulation layer 219a may include an insulation material, for example, silicon oxide, silicon nitride, and/or silicon nitroxide, and may be formed by using various methods including a PECVD method, an APCVD method, and an LPCVD method.

The first insulation layer 219a may be disposed between the active layer 211 and a gate electrode 213 of the TFT, and accordingly, may function as a gate insulation film of the TFT. In addition, the first insulation layer 219a may be disposed between a lower electrode and an upper electrode of the storage capacitor (not shown), and accordingly, may function as a dielectric layer of the storage capacitor. Here, in order to increase capacitance of the storage capacitor, the first insulation layer 219a may include an insulation material having great permittivity. For example, the first insulation layer 219a may have a stack structure of silicon nitride that is disposed between a lower silicon oxide and an upper silicon oxide and has greater permittivity than that of a silicon oxide.

The gate electrode 213 may be arranged within a predetermined region on the first insulation layer 219a. The gate electrode 213 may be connected to gate lines (not shown) to which control signals for controlling the TFT are applied. According to control signals applied to the gate electrode 213 by the gate lines, the TFT may be electronically conducted.

The gate electrode 213 concerning adhesion to adjacent layers, surface planarization of layers to be stacked, and processability may be formed in, for example, a single layer or a multilayer of one or more materials selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the gate electrode 213 may have a stack structure of Mo/Al/Mo.

A second insulation layer 219b including an insulation material, for example, silicon oxide, silicon nitride, and/or silicon nitroxide, may be disposed on the gate electrode 213. The second insulation layer 219b may have a multilayer structure.

The first insulation layer 219a and the second insulation layer 219b may have a contact hole exposing the source and drain regions of the active layer 211. A source electrode 215a and a drain electrode 215b may be electronically connected to the source region and the drain region, respectively, through contact holes of the first insulation layer 219a and the second insulation layer 219b.

The source electrode 215a and the drain electrode 215b may be formed in, for example, a single layer or a multilayer of one or more materials selected from Al, Pt, Pd, Ag, Mg, Au, Ni, Nd, Ir, Cr, Li, Ca, Mo, Ti, W, and Cu, in consideration of conductivity of the source electrode 215a and the drain electrode 215b.

To protect the formed TFT, a third insulation layer 219c covering the TFT may be further provided.

The third insulation layer 219c may include an inorganic insulation layer and/or an organic insulation layer. Examples of the inorganic insulation material that may be used in the third insulation layer 219c include silicon oxide (SiO₂), silicon nitride (SiNₓ), silicon nitroxide (SiON), aluminum oxide (Al₂O₃), titanium oxide (TiO₂), tantalum oxide (Ta₂O₅), hafnium oxide (HfO₂), zirconium oxide (ZrO₂), barium strontium titanate (BST), and lead zirconate-titanate (PZT). Examples of the organic insulation material that may be used in the third insulation layer 219c include a typical commercial polymer (PMMA, PS), a polymer derivative including a phenol-based group, an acryl-based polymer, an imide-based polymer, an aryl ether-based polymer, an amide-based polymer, a fluorinated polymer, a p-xylene-based polymer, a vinyl alcohol-based polymer, and a blend thereof.

The third insulation layer 219c may have a composite stack structure of an inorganic insulation layer and an organic insulation layer. As illustrated in the drawings, when an OLED is disposed on top of a TFT, the organic insulation layer may function as a planarization layer for planarizing an upper surface of the inorganic insulation layer that covers the TFT.

An OLED layer 220 including an OLED may be arranged within an emission region on top of the third insulation layer 219c.

The OLED layer 220 may include a pixel electrode 221 formed on the third insulation layer 219c, a counter electrode 225 disposed opposite to the pixel electrode 221, and an interlayer 223 disposed between the pixel electrode 221 and the counter electrode 225. When voltage is applied between the pixel electrode 221 and the counter electrode 225, the interlayer 223 may emit light. Here, the interlayer 223 may emit blue light, green light, red light, or white light.

The third insulation layer 219c may include a contact hole that exposes at least one of the source electrode 215a and the drain electrode 215b. The pixel electrode 221 may be connected to at least one of the source electrode 215a and the drain electrode 215b through the contact hole, and accordingly, may be electronically connected to the TFT.

According to light emission orientation, the organic light-emitting display apparatus may be classified into a bottom emission type apparatus, a top emission type apparatus, and a dual emission type apparatus. In the case of the bottom emission type organic light-emitting display apparatus, the pixel electrode 221 may be provided as a light transmission electrode and the counter electrode 225 may be provided as a reflective electrode. In the case of the top emission type organic light-emitting display apparatus, the pixel electrode 221 may be provided as a reflective electrode and the counter electrode 225 may be provided as a transflective electrode. The organic light-emitting display apparatus according to embodiments of the present invention is described on the basis of a top emission type organic light-emitting display apparatus in which an OLED emits light in a direction toward an encapsulation unit 300.

The pixel electrode 221 may be a reflective electrode and have a stack structure of a reflective layer and a transparent electrode layer having high work function. The reflective layer may include Ag, Mg, Al, Pt, Pd, Au, Ni, Nd, Ir, Cr, or an alloy thereof. The transparent electrode layer may include at least one selected from transparent conductive oxides, such as indium tin oxide (ITO), indium zinc oxide (IZO), zinc oxide (ZnO), indium oxide (In₂O₃), indium gallium oxide (IGO), and aluminum zinc oxide (AZO). However, the present invention is not limited thereto, and that is, the transparent electrode layer may be formed of various materials and in various structures including a single layer or a multilayer. In addition, the pixel electrode 221 may function as an anode electrode.

In addition, a pixel define layer 230 that covers edges of the pixel electrode 221 and includes a predetermined opening portion exposing a central part of the pixel electrode 221 may be disposed on the pixel electrode 221. The pixel define layer 230 may be formed of, for example, an organic material, such as PI.

The interlayer 223 that includes an organic light-emitting layer for emitting light may be disposed on a region defined by the opening portion. Then, the region on which the interlayer 223 is disposed may be defined as an emission region. If an emission region is formed within the opening portion of the pixel define layer 230, a region that is projected by the pixel define layer 230 may be arranged between the emission regions. In this regard, an organic light-emitting layer may not be formed on the projected region, which may be thereby defined as a non-emission region.

The counter electrode 225 may be formed as a transparent electrode, and may be a transflective film in which a thin metal film is formed by using metals having small work function, such as Li, Ca, LiF/Ca, LiF/Al, Al, Mg, and Ag. In order to compensate for high resistance problems of the transflective thin metal film, a transparent conductive layer formed of a conductive oxide may be disposed on the transflective thin metal film. The counter electrode 225 as a common electrode may be formed over the entire surface of the flexible substrate 100. In addition, the counter electrode 225 may function as a cathode electrode.

The pixel electrode 221 and the counter electrode 225 may have opposite polarities to each other.

The interlayer 223 may include an organic light-emitting layer that emits light, and the organic light-emitting layer may be formed by using a low molecular weight organic material or a high molecular weight organic material. When the organic light-emitting layer is a low molecular weight organic layer formed a low molecular weight organic material, a hole transport layer (HTL) and a hole injection layer (HIL) may be provided in a direction toward the pixel electrode 221 with respect to the organic light-emitting layer, and an electron transport layer (ETL) and an electron injection layer (EIL) may be provided in a direction toward the counter electrode 225 with respect to the organic light-emitting layer. Alternatively, other functional layers in addition to these HIL, HTL, ETL, and EIL may be stacked thereon.

When the organic light-emitting layer is a high molecular weight organic layer formed of a high molecular weight organic material, a HTL may be provided alone in a direction toward the pixel electrode 221 with respect to the organic light-emitting layer. The high molecular weight HTL may be formed on top of the pixel electrode 221 according to an ink-jet printing method or a spin-coating method by using poly-(2,4)-ethylene-dihydroxy thiophene (PEDOT) or polyaniline (PANI).

The structure that the OLED layer 220 is disposed on the device/wiring layer 210 on which the TFT is disposed is described, but the present invention is not limited thereto. The organic light-emitting display apparatus may have various structures including a structure in which the pixel electrode 221 of the OLED is formed on a layer that is the same as that of the active layer 211 of the TFT, a structure that the pixel electrode 221 of the OLED is formed on the same layer with that of the gate electrode 213 of the TFT, or a structure in which the pixel electrode 221 of the OLED is formed on a layer that is the same as that of the source and drain electrodes 215a and 215b.

In some other embodiments, the TFT may include the gate electrode 213 that is disposed on top of the active layer 211, but the present invention is not limited thereto. The TFT may include the gate electrode 213 that is disposed below the active layer 211.

The encapsulation unit 300 may be disposed on the substrate 100 to encapsulate the display unit 200. The OLED included in the display unit 200 and formed of an organic material may be easily deteriorated by moisture or oxygen outside the OLED. Thus, in terms of protecting the display unit 200, the display unit 200 needs to be encapsulated. The encapsulation unit 300 may include a hybrid protective film 310 to encapsulate the display unit 200. Here, the hybrid protective film 310 may consist of an inorganic part layer 313 where carbon is removed, an organic part layer 311 where carbon is contained in a predetermined amount, and a gradient part layer 312 disposed between the inorganic part layer 313 and the organic part layer 311 and increasing an amount of carbon as being more contiguous to the organic part layer 311.

Although the hybrid protective film 310 is distinguished by the organic part layer 311, the gradient part layer 312, and the inorganic part layer 313, in terms of performing a single process of coating and plasma treatment, the hybrid protective film 310 is different from a stack structure of an organic material layer and an inorganic material layer. That is, in regard to the stack structure of the organic material layer and the inorganic material layer, there are two or more deposition processes to be done by sequentially stacking an organic material layer and an inorganic material. However, in regard to the hybrid protective film 310, an organic-inorganic composite layer is formed on the hybrid protective film 310, and then, carbon components are removed from the exposed top surface of the hybrid protective film 310 by performing the plasma treatment. Accordingly, the hybrid protective film 310 may include the inorganic part layer 313 where carbon is removed, a gradient part layer 312 where some carbon components are still remained, but the carbon amount is decreased as being more contiguous to the inorganic part layer 313, and the organic part layer 311 where carbon is not removed, but remained in a predetermined amount.

The inorganic part layer 313 and the gradient part layer 312 may be formed to a uniform thickness by performing the plasma treatment. However, since the organic part layer 311 is not affected by the plasma treatment, the organic part layer 311 may be formed thick on the OLED while formed thin on the pixel define layer 230.

In addition, since the hybrid protective film 310 is formed by the plasma treatment, it may easily protect side surfaces of the display unit 200. The hybrid protective film 310 disposed on the side surfaces of the side display unit 200 may include the organic part layer 311, the gradient part layer 312, and the inorganic part layer 313 that are disposed substantially parallel to the side surfaces.

An interface between the organic part layer 311 and the gradient part layer 312 and an interface between the gradient part layer 312 and the inorganic part layer 313 may not be clearly distinguishable. Such interfaces that are not clearly distinguishable may contribute to provide better moisture and oxygen blocking efficiency. In regard to the stack structure of the organic material layer and the inorganic material layer, an interface between the organic material layer and the inorganic material layer is so distinguishable that permeation of moisture or oxygen may happen through the interface between the organic material layer and the inorganic material layer.

Although not illustrated herein, a halogenated metal layer including LiF may be additionally disposed between the display unit 200 and the encapsulation unit 300. The halogenated metal layer may prevent damage to the display unit 200 when the encapsulation unit 300 is formed of an inorganic material by using a sputtering method or a plasma deposition method. In addition, an interlayer may be disposed between the display unit 200 and the encapsulation unit 300. Examples of suitable materials for the interlayer include an organic material, such as polyimide, polynorbornene, polycarbonate, polyparaxylene, or parylene, or an inorganic material, such as silicon oxide, silicon nitride, silicon nitroxide, aluminum oxide, aluminum nitride, titanium oxide, or titanium nitride.

The hybrid protective film 310 including the organic part layer 311, the gradient part layer 312, and the inorganic part layer 313 will be now described in detail.

The hybrid protective film 310 may include silicon and at least one inorganic atom other than silicon, and have a compositionally gradient interface structure in which a concentration of an organic functional group gradually changes in a thickness (or depth) direction of the hybrid protective film 310.

The expression “the hybrid protective film 310 has a compositionally gradient interface structure” refers that the hybrid protective film 310 is formed of an organic-inorganic composite material, and in a thickness (depth) direction of the hybrid protective film 310, a composition changes gradually without any rapid change, and in a thickness direction of the hybrid protective film 310 away from the bottom surface (i.e., a surface in a direction toward the substrate 100) to the upper surface (i.e., a surface in a direction away from the substrate 100) of the hybrid protective film 310, the hybrid protective film 310 has a portion in which the ratio of carbon gradually decreases. That is, as described above, the hybrid protective film 310 may consist of three part layers, i.e., the organic part layer 311, the gradient part layer 312, and, inorganic part layer 313, and a composition thereof does not rapidly change at the interfaces between each of the part layers.

The hybrid protective film 310 may have a skeleton of a network structure including —O—Si—O— linkages, which are shown in silicate. Such a network structure may include silicon, oxygen, hydrogen, and carbon, wherein some of silicon atoms are directly linked to carbon atoms that constitute a part of an organic functional group by covalent bond. For example, in the network structure, some silicon atoms may be linked to four oxygen atoms, and other silicon atoms may be linked to an organic functional group, such as an alkyl group, an aryl group, a fluoroalkyl group, a vinyl group, an acryl group, a methacryl group, or an epoxy group, by a Si—C bond. In addition, a silicon atom of the network structure to which an organic functional group is linked by a Si—C bond may be linked to one organic functional group.

At least one other element may be further included in the network structure. The other element included in the network structure of the hybrid protective film 310 may be at least one element selected from alkali metal, alkali earth metal, transition metal, post transition metal, metalloid, boron (B), and phosphorous (P). In the hybrid protective film 310, the other element may exist in an oxide form in an interstitial location inside the network structure, or may be linked to a silicon atom constituting the skeleton of the network structure by the covalent bond of other element-oxygen-silicon form. That is, when the other element is referred to as M, some of the other elements may exist in an oxide form of MₘOₙ, a hydroxide form, or an oxide form containing a hydroxyl group in the interstitial location without a direct bond to the —O—Si—O— skeleton of the network structure. Some of the other elements may, like -M-O—Si—, directly chemically bond to the skeleton of the network structure. Since the other element is bonded to an oxygen atom in both cases, the other element included in the hybrid protective film 310 may be considered as an oxide.

As described above, the hybrid protective film 310 has a compositionally gradient interface structure, and includes the organic part layer 311, the gradient part layer 312, and the inorganic part layer 313 that are sequentially stacked on the display unit 200 in this stated order.

In the following description, the direction toward the organic part layer 311 from the inorganic part layer 313, or vice versa, is referred to as a “thickness” or “depth” direction of the hybrid protective film 310. In addition, the term “inorganic part layer 313” used herein refers to a part layer of the hybrid protective film 310 located close to the upper surface of the hybrid protective film 310 from which carbon is not substantially detected. In terms of manipulation of a measurement device, the wording “carbon is not substantially detected in the inorganic part layer 313” may be actually identified by measuring a molar fraction of a carbon atom by, for example, X-ray photoelectron spectroscopy (XPS). A signal that is generally used in measuring the molar fraction of a carbon atom in XPS is a spectral signal induced from 1 s energy level of a carbon atom. The wording “a carbon atom is not substantially detected in the inorganic part layer 313 based on XPS” refers that an intensity of the signal of a carbon atom is not statistically significantly greater than that of noise signals.

The inorganic part layer 313 may include as a major component, for example, silicon and oxygen, which occupy a molar fraction of 99% or more of all atoms constituting the inorganic part layer 313. When other element is further included, the inorganic part layer 313 may include as a major component, for example, silicon, oxygen, and an element other than carbon which will be described later. From the substantially non-detection of carbon in the inorganic part layer 313, it is confirmed that the inorganic part layer 313 does not contain carbon that forms a Si—C bond in a silicon atom. However, the inorganic part layer 313 may include a silicon atom that is bonded to four oxygen atoms and forms an —O—Si—O— linkage as the skeleton of the network structure. The inorganic part layer 313 of the hybrid protective film 310 plays a role in preventing permeation of oxygen and moisture due to dense composition thereof.

The “organic part layer 311” used herein refers to a part layer of the hybrid protective film 310 that is near to the bottom surface of the hybrid protective film 310 from which carbon is detected in a predetermined amount. Some silicon atoms of the organic part layer 311 are directly bonded to carbon atoms that constitute an organic functional group and form the —O—Si—O— linkage as the skeleton of the network structure, and other silicon atoms of the organic part layer 311 are bonded to four oxygen atoms and are linked to the skeleton of the network structure. In addition, the organic part layer 311 may include other elements described above. The organic part layer 311 may provide tight contact between the display unit 200 and the encapsulation unit 300 based on its affinity with respect to the surface of the display unit 200 (i.e., the counter electrode 225) located at the bottom.

The “gradient part layer 312” used herein refers to a part layer that is disposed between the inorganic part layer 313 and the organic part layer 311, and a region having a carbon amount gradually monotone-increasing in a thickness direction from the inorganic part layer 313 to the organic part layer 311. That is, the carbon amount of the gradient part layer 312 is substantially zero at the interface between the gradient part layer 312 and the inorganic part layer 313, gradually increases in the thickness direction, and at the interface between the gradient part layer 312 and the organic part layer 311, the carbon amount increases up to a carbon amount of the organic part layer 311.

Since carbon is not substantially detected in the “inorganic part layer 313”, the inorganic part layer 313 may be regarded as an inorganic material layer that contains, as a major component, silicon and oxygen. Although the organic part layer 311 is named as an organic part layer herein, the skeleton of the organic part layer 311 may also include silicon and oxygen, and some silicon atoms may not be bonded to an organic functional group. Accordingly, the organic part layer 311 may have an organic-inorganic composite material structure including an organic functional group and an inorganic functional group. As described above, the gradient part layer 312 may also have an organic-inorganic composite material structure. Therefore, the hybrid protective film 310 that includes the inorganic part layer 313, the gradient part layer 312, and the organic part layer 311 may be referred to as an organic-inorganic composite layer.

In the case of including the other element in the network structure, since the other element is an inorganic material, the inorganic part layer 313 is referred to as an inorganic material layer, and accordingly, the gradient part layer 312 and the organic part layer 311 may refer to have an organic-inorganic composite material structure.

The compositionally gradient interface structure is a structure in which the carbon amount changes in a thickness (depth) direction of the hybrid protective film 310, and amounts of silicon and the other element do not change as much as that of carbon. In particular, amounts of silicon and the other element in the hybrid protective film 310 may be substantially homogeneous throughout the hybrid protective film 310. For example, amounts of silicon and the other element in the hybrid protective film 310 may change within ±10 wt % or ±7 wt % in the thickness direction of the hybrid protective film 310.

The hybrid protective film 310 includes the inorganic part layer 313, the gradient part layer 312, and the organic part layer 311, wherein interfaces therebetween are clearly not distinguishable from each other. Since the hybrid protective film 310 has a compositionally gradient interface structure in which a composition thereof gradually changes, due to the dense composition of the inorganic part layer 313, excellent moisture and oxygen blocking effects and high mechanical strength may be obtained, and at the same time, due to the gradient part layer 312, a rapid change of properties may be buffered to secure flexibility, and due to the organic part layer 311, high affinity with the upper surface of the display unit 200 may be obtained. In addition, since a composition gradually changes in the hybrid protective film 310 that is integrated by a chemical bond, the inorganic part layer 313 is not exfoliated from the gradient part layer 312, and likewise, the gradient part layer 312 is not exfoliated from the organic part layer 311. The hybrid protective film 310 may less experience cracks and exfoliation resulting from a difference in properties of layers than typical thin-film encapsulation formed by stacking an inorganic material layer separately on an organic material layer by chemical deposition or sputtering, and the protective film 310 may also have flexibility and strength at the same time.

Furthermore, in the hybrid protective film 310 according to an embodiment of the present invention, elements other than carbon are directly linked to the —O—Si—O— skeleton of the hybrid protective film 310 via oxygen, or exist in the interstitial location of the network structure of the hybrid protective film 310. Accordingly, a more dense structure may be obtained, and surface hardness is significantly increased. In addition, a refractive index of the hybrid protective film 310 may be controlled by appropriately controlling the kind and amount of other element. For example, when there is a target refractive index for the hybrid protective film 310, an oxide of other element having a refractive index closer to the target refractive index than a refractive index of the organic-inorganic composite layer formed without the other element may be selected, and the selected other element may be added to the organic-inorganic composite layer to obtain a refractive index more closely to the target refractive index.

Since the hybrid protective film 310 has a network structure having —O—Si—O— linkages as a skeleton, a transparent property of the hybrid protective film 310 may be obtained according to selection of other elements. In the hybrid protective film 310, amounts of components including the other element may be determined in such a way that a refractive index of the hybrid protective film 310 is in a range of about 1.4 to about 2.5 with respect to light having a wavelength of 632 nm at a temperature of 25° C., and a light transmittance of the hybrid protective film 310 is 80% or more with respect to light having a wavelength of 550 nm at a temperature of 25° C. When the hybrid protective film 310 has a refractive index in a range of about 1.4 to about 2.5 and a layer with material properties different from the hybrid protective film 310 is necessarily stacked, matching of their refractive indexes is easy and thus, a final organic light-emitting display apparatus 1000 may have excellent light transmittance characteristics. In addition, when the light transmittance of the hybrid protective film 310 is 80% or more, clearance of the organic light-emitting display apparatus 1000 may be improved. For example, a light transmittance of the hybrid protective film 310 may be 85% or more. However, the light transmittance of the hybrid protective film 310 may be actually about 90% or less in consideration of costs and limitation of properties of a source material. However, the light transmittance of the hybrid protective film 310 may also be higher than 90%, and is not limited thereto.

The hybrid protective film 310 may further include other element, and the other element may be selected from the group consisting of lithium (Li), sodium (Na), potassium (K), rubidium (Rb), cesium (Cs), beryllium (Be), magnesium (Mg), calcium (Ca), strontium (Sr), barium (Ba), titanium (Ti), zirconium (Zr), hafnium (Hf), vanadium (V), niobium (Nb), molybdenum (Mo), tungsten (W), tellurium (Te), rhenium (Re), nickel (Ni), zinc (Zn), aluminum (Al), gallium (Ga), indium (In), thallium (TI), tin (Sn), boron (B), phosphorous (P), and a combination thereof. In addition, an atomic number ratio of the other element to silicon in the hybrid protective film 310 may be in a range of 1:20 to 20:1, or in a range of 1:10 to 10:1. When the ratio of the other element to silicon is selected within this range, the hybrid protective film 310 may have a dense structure, and thus, moisture and oxygen blocking properties of the hybrid protective film 310 may be further improved.

The amount of carbon atoms included in the inorganic part layer 313 may be a molar ratio of 1% or less. In other words, 1% carbon corresponds to a level of noise signals of XPS and thus, carbon is not substantially detected.

When the hybrid protective film 310 further includes other element, the amount of carbon atoms included in the inorganic part layer 313 may satisfy the following equation of N_{carbon}/(N_{carbon}+N_{silicon}+N_{oxygen}+N_{other element})≦0.01, wherein N_{carbon} is the number of carbon atoms, N_{silicon} is the number of silicon atoms, N_{oxygen} is the number of oxygen atoms, and N_{other element} is the number of the other element. Although —Si—O—Si— or -M-O—Si— contributes to a dense network structure, an end functional group having a carbon-hydrogen (C—H) bond, such as Si—CHₓ or Si-alkyl, may function as a defect in the network structure and may deteriorate gas blocking characteristics. When an amount of the carbon atom is within this range, internal defects generated due to a functional group with a C—H bond may be minimized, and accordingly, the inorganic part layer 313 may have excellent gas blocking characteristics.

A surface hardness of the inorganic part layer 313 is 6H or more when measured by using a pencil hardness tester.

The network structure of the hybrid protective film 310 may include both a silicon atom (inorganic silicon) that is not directly bonded to carbon constituting an organic functional group and a silicon atom (organic silicon) that is directly bonded to carbon constituting an organic functional group. In this regard, the organic part layer 311 of the hybrid protective film 310 may include only organic silicon, or in some other embodiments, may include both organic silicon and inorganic silicon. When the network structure of the organic part layer 311 includes a silicon atom (inorganic silicon) that is not directly bonded to carbon constituting an organic functional group, a ratio of the inorganic silicon atom to a silicon atom (organic silicon) that is directly bonded to carbon constituting an organic functional group in the organic part layer 311, i.e., an organic silicon:inorganic silicon, may be less than 1:10. When the atomic number ratio of the inorganic silicon to the organic silicon in the organic part layer 311 is smaller than this range, the hybrid protective film 310 may retain an appropriate flexibility without cracking even when exposed to external stress.

The organic functional group in the hybrid protective film 310 may be directly linked to a silicon atom by a Si—C bond and may not be bonded to an oxygen atom. For example, the organic functional group may be linked to a silicon atom, like R—Si, not RO—Si, wherein R is the organic functional group. The hybrid protective film 310 that does not contain an organic functional group bonded to an oxygen atom may further increase light transmittance, and compared to when an organic functional group bonded to an oxygen atom, like RO—Si, is used, a higher density may be obtained and thus, higher gas blocking performance may be obtained at the same thickness.

The number of organic functional groups directly bonded to a silicon atom (organic silicon) may be 3 or less in average. For example, the number of organic functional groups directly bonded to organic silicon may be 2 or less. For example, the number of organic functional groups directly bonded to organic silicon may be 1.

The organic functional groups may be cross-linked, and such cross-linking may be a carbon-carbon single bond.

A thickness of the hybrid protective film 310 may be in a range of about 0.1 μm to about 10 μm.

The hybrid protective film 310 may have an excellent water vapor transmission rate of 0.015 g/m²/day or less at a temperature of 37.8° C. in a relative humidity of 100%. In particular, the water vapor transmission rate of 0.015 g/m²/day obtainable in the hybrid protective film 310 is one order less than a water vapor transmission rate of 10⁻¹ g/m²/day obtainable in an inorganic layer obtained by using a typical sputtering process. In terms of light transmittance, the hybrid protective film 310 has a light transmittance of 88.5%, which is similar with that of a typical inorganic layer (91.1%), with respect to light having a wavelength of 550 nm.

The hybrid protective film 310 may have an oxygen transmission rate in a range of 10⁻¹ cm³/m²/day to 10⁻² cm³/m²/day at a temperature of 35° C. in a relative humidity of 0%. In particular, the oxygen transmission rate of 10⁻² cm³/m²/day obtainable in the hybrid protective film 310 is one order less than a minimum oxygen transmission rate (10⁻¹ cm³/m²/day) obtainable by using typical plasma-enhanced chemical vapor deposition (PECVD).

Another aspect of the present invention provides a method of manufacturing the hybrid protective film 310 in detail.

The method of manufacturing the hybrid protective film 310 includes:

a) preparing an organic-inorganic composite coating solution by performing sol-gel hydrolysis and condensation on an organic-inorganic mixed solution including at least one organosilane represented by Formula 1 below, at least oxide precursor, water, and optionally, at least one silicate ester represented by Formula 2 below to form an organic-inorganic composite coating solution,

b) forming an organic-inorganic composite layer by coating and curing the organic-inorganic composite coating solution on the surface of the display unit 200 on the substrate 100; and

c) treating the surface of the organic-inorganic composite layer with plasma of reactive gas to form a hybrid protective film 310.

Here, the plasma treatment in step c) in manufacturing the hybrid protective film 310 may be performed until the inorganic part layer 313 from which carbon is not detected is formed inside the hybrid protective film 310 to a predetermined thickness.

In step a), at least one organosilane, at least one oxide precursor, water, and optionally, at least one silicate ester may be mixed together to prepare the organic-inorganic mixed solution.

In some other embodiments, the organic-inorganic mixed solution may include, without an oxide precursor, at least one organosilane, water, and optionally, at least one silicate ester. In this case, the hybrid protective film 310 does not include other element.

The organosilane and silicate ester may include, as each shown in Formula 1 and Formula 2, a hydrolysable functional group, such as an alkoxy group and an aryloxy group, at any stoichemically possible ratios. The organosilane may further include a non-hydrolyzable organic functional group, in addition to the alkoxy group and/or the aryloxy group. In the organosilane, the non-hydrolyzable organic functional group and the hydrolyzable functional group may be used together in any stoichemically possible combination.

A¹ₗA²ₘA³ₙSi(OE¹)ₚ(OE²)_{q}(OE³)ᵣ [Formula 1]

Si(OG¹)_{α}(OG²)_{β}(OG)_{γ}(OG⁴)_{δ} [Formula 2]

In Formula 1, A¹, A², and A³ are each independently a C₁-C₂₀ alkyl group, a C₁-C₂₀ fluoroalkyl group, a C₆-C₂₀ aryl group, a vinyl group, an acryl group, a methacryl group, or an epoxy group. In Formula 1, l, m, and n are each independently 0 or an integer, and satisfy the equation of 1≦l+m+n≦3. In Formula 1, E¹, E², and E³ are each independently a C₁-C₁₀ alkyl group, a C₁-C₁₀ fluoroalkyl group a C₆-C₂₀ aryl group, a C₁-C₂₀ alkyloxyalkyl group, a C₁-C₂₀ fluoroalkyloxyalkyl group, a C₁-C₂₀ alkyloxyaryl group, a C₆-C₂₀ aryloxyalkyl group, or a C₆-C₂₀ aryloxyaryl group. In Formula 1, p, q, and r are each independently 0 or an integer of 1 to 3, and satisfy the equation of 1≦p+q+r≦3 and the equation of l+m+n+p+q+r=4.

In Formula 2, G¹, G², G³, and G⁴ are each independently a C₁-C₁₀ alkyl group, a C₁-C₁₀ fluoroalkyl group, a C₆-C₂₀ aryl group, a C₁-C₂₀ alkyloxyalkyl group, a C₁-C₂₀ fluoroalkyloxyalkyl group, a C₁-C₂₀ alkyloxyaryl group, a C₆-C₂₀ aryloxyalkyl group, or a C₆-C₂₀ aryloxyaryl group. In Formula 2, α, β, γ, and δ are each independently 0 or an integer of 1 to 4, and satisfy the equation of α+β+γ+δ=4.

The oxide precursor may include at least one other element selected from alkali metal, alkali earth metal, transition metal, post-transition metal, metalloid, boron atom, and phosphorous. In addition, the oxide precursor may be capable of forming a diatomic oxide of the other element and oxygen through sol-gel hydrolysis.

The sol-gel synthesis process for the preparation of the organic-inorganic composite coating solution from the organic-inorganic mixed solution is a well known technique in the art and thus, will not be described herein. Organosilane, silicate ester, a hydrolyzable oxide precursor are all starting materials widely used for sol-gel hydrolysis and condensation. Briefly, organosilane, an oxide precursor that is to provide an oxide of an element other than carbon, water, and optionally, silicate ester may be mixed together to prepare an organic-inorganic mixed solution. In this regard, the organic-inorganic mixed solution may include a solvent and a catalyst. As described above, the oxide precursor that is to provide an oxide of an element other than carbon may not be optionally included in the organic-inorganic mixed solution.

In regard to the sol-gel hydrolysis on the organic-inorganic mixed solution, a hydrolysable functional group, such as an alkoxy group or an aryloxy group, is hydrolyzed from silane components to form a Si—OH functional group, and in regard to the condensation, the Si—OH functional group is condensed while water is removed therefrom to link to —O—Si—O— linkages to form a network structure. In this regard, when the oxide precursor of the other element includes a hydrolysable functional group, the oxide precursor be also hydrolyzed, and through a further condensation reaction, the oxide precursor may be linked to the —O—Si—O— linkages or placed in an oxide form in the interstitial location of the network structure. In some embodiments, some oxide precursors may be converted into oxides in the subsequent plasma treatment in step c). As a result of the hydrolysis and condensation, an organic-inorganic composite coating solution may be formed.

Since the organic-inorganic mixed solution is prepared by mixing at least one organosilane, at least one oxide precursor, water, and optionally, at least one silicate ester, various kinds of organic-inorganic mixed solution may be formed. In some embodiments, silicate ester and a polar solvent are mixed and an organosilane is added thereto while stirring the mixture to perform a hydrolysis reaction and a condensation reaction. From the organic-inorganic mixed solution, moisture, alcohol component, or a catalyst is removed by extraction or dialysis, thereby finally preparing an organic-inorganic composite coating solution.

In some other embodiments, in step a), organosilane and silicate ester used in preparing the organosilane and silicate ester may be represented by Formula 3 and Formula 4 below, respectively.

R¹ₓSi(OR²)₍₄₋ₓ₎ [Formula 3]

Si(OR³)₄ [Formula 4]

In Formula 3, R¹ is a C₁-C₂₀ alkyl group, a C₆-C₂₀ aryl group, or a C₁-C₂₀ alkyl group including a vinyl group, an acryl group, a methacryl group, or an epoxy group. In Formula 3, R² is a C₁-C₁₀ alkyl group or C₁-C₁₀ alkyloxyalkyl group, and x is an integer of 1 to 3, for example, x is 1 or 2.

In Formula 4, R³ is a C₁-C₁₀ alkyl group or a C₁-C₁₀ alkyloxyalkyl group.

When organic trialkoxysilane and tetra-alkyl silicate respectively represented by Formulae 3 and 4 are used as organosilane and silicate ester, low material costs, ease of accessibility, and reactivity may be obtained.

In an embodiment of the present invention, as the organosilane of Formula 1, trialkoxysilane (R²Si(OR³)₃) obtained by substituting x of Formula 1 with 1, or dialkoxysilane ((R²)₂Si(OR³)₂) obtained by substituting x of Formula 1 with 2.

Non-limiting examples of trialkoxysilane (R²Si(OR³)₃) are methyltrimethoxysilane, methyltriethoxysilane, ethyltrimethoxysilane, ethyltriethoxysilane, propylethyltrimethoxysilane, methyltripropoxysilane, 3-glycidoxypropyltrimethoxysilane, 3-glycidoxypropyltriethoxysilane, 3-acryloxypropyltrimethoxysilane, 3-acryloxypropyltriethoxysilane, 3-metacryloxypropyltrimethoxysilane, 3-metacryloxypropyltriethoxysilane, vinyltriethoxysilane, vinyltrimethoxysilane, vinyltriethoxysilane, vinyltripropoxysilane, phenyltrimethoxysilane, 2-(3,4-epoxycyclohexyl)ethyltrimethoxysilane, and heptadecafluorodecyltrimethoxysilane, but are not limited thereto.

Non-limiting examples of dialkoxysilane ((R²)₂Si(OR³)₂) are dimethyldimethoxysilane, dimethyldiethoxysilane, diethyldimethoxysilane, and diethyldiethoxysilane, but are not limited thereto.

Non-limiting examples of silicate ester of Formula 2 are tetraethyl orthosilicate (TEOS), tetramethyl orthosilicate, tetraisopropoxysilicate, tetrabutoxysilicate, tetraethoxyethylsilicate, and other silicate esters, but are not limited thereto.

When silicate ester is included in preparing the organic-inorganic mixed solution according to an embodiment of the present invention, a molar ratio of silicate ester to organosilane is in a range of 1:10 to 10:1. When the ratio of silicate ester to organosilane is within this range, the organic-inorganic composite layer in step b) and the hybrid protective film 310 in step c) may not crack when exposed to external stress and may have an appropriate level of flexibility. By controlling the ratio of the silicate ester to the organosilane, the carbon content in the final hybrid protective film 310 may be determined.

The other element, which is a major atom of the oxide precursor used for the organic-inorganic mixed solution, may be any one of metal elements and metalloid elements, not carbon, that are hydrolyzed to form an other element-oxygen-other element bond or an other element-oxygen-silicon bond and may be partially non-metals. The term ‘metal’ used herein refers to a group consisting of alkali metal, alkaline earth metal, transition metal, post transition metal, metalloid, and non-metal.

Examples of the oxide precursor used for the organic-inorganic mixed solution are listed below, but are not limited thereto.

Examples of a precursor of a non-metal other element are, in the case of boron (III), boric acid and trimethyl borate. In addition, examples of a precursor of a non-metal other element are, in the case of phosphorous (P), phosphoric acid, phosphorus oxychloride, phosphorus pentoxide, and C₁-C₆ alkylphosphates (for example, methyl phosphate, ethyl phosphate, dimethyl phosphate, trimethyl phosphate, and triethyl phosphate).

In some other embodiments, the oxide precursor may be a metal oxide precursor, and the metal oxide precursor may be represented by Formula 5 below.

M-Lₙ [Formula 5]

In Formula 5, M is a metal selected from Li(I), Na(I), K(I), Rb(I), Cs(I), Be(II), Mg(II), Ca(II), Ti(IV), Ta(V), Zr(FV), Hf(IV), Mo(V), W(V), Zn(II), Al(III), Ga(III), In(III), Tl(III), Ge(IV), Sn(IV), and Sb(III). In Formula 5, L is a (hydrolyzable) decomposable functional group, for example, halogen (e.g., F⁻, Cl⁻, Br⁻, and I⁻, in particular Cl⁻ and Br⁻), nitrate (NO₃⁻), a C₁-C₆ alkoxy (in particular, methoxy, ethoxy, n-propoxy, i-propoxy and n-butoxy, i-butoxy, sec-butoxy or tert-butoxy, n-pentyloxy, and n-hexyloxy), a C₆ to C₁₀ aryloxy (in particular, phenoxy), a C₁ to C₄ acyloxy (in particular, acetoxy and propionyloxy), alkylcarbonyl (e.g., acetyl), or acetylacetone. In Formula 5, n is determined by oxidation number of metal, and for example, in the case of Li(I), Na(I), K(I), Rb(I), and Cs(I), n=1, in the case of Be(II), Mg(II), Ca(II), and Zn(II), n=2, in the case of Al(III), Ga(III), In(III), Tl(III), B(III), and Sb(III), n=3, in the case of Ti(IV), Zr(IV), Hf(IV), Ge(IV), and Sn(IV), n=4, and in the case of Ta(V), Mo(V), and W(V), n=5.

Some examples of a precursor of alkali metals are as follows:

in the case of Li(I), the examples include lithium acetate, lithium bromide, lithium carbonate, lithium chloride, lithium nitrate, and lithium iodide;

in the case of Na(I), the examples include sodium acetate, sodium bromide, sodium carbonate, sodium chloride, sodium nitrate, sodium iodide, sodium ethoxide, and sodium methoxide;

in the case of K(I), the examples include potassium acetate, potassium bromide, potassium carbonate, potassium chloride, potassium nitrate, and potassium iodide;

in the case of Rb(I), the examples include rubidium acetate, rubidium bromide, rubidium carbonate, rubidium chloride, rubidium nitrate, and rubidium iodide; and

in the case of Cs(I), the examples include cesium acetate, cesium bromide, cesium carbonate, cesium chloride, cesium nitrate, and cesium iodide.

Some examples of a precursor of alkaline earth metals are as follows:

in the case of Be(II), the examples include beryllium acetylacetonate, beryllium chloride, and beryllium nitrate;

in the case of Mg(II), the examples include magnesium acetate, magnesium bromide, magnesium carbonate, magnesium chloride, magnesium ethoxide, magnesium fluoride, magnesium formate, and magnesium iodide; and

in the case of Ca(II), the examples include calcium acetate, calcium bromide, calcium carbonate, calcium chloride, calcium fluoride, calcium formate, and calcium iodide.

Some examples of a precursor of transition metals are as follows:

in the case of Ti(IV), the examples include titanium chloride dihydrate, titanium tert-butoxide, titanium n-butoxide, titanium 2-ethylhexyloxide, titanium ethoxide, titanium methoxide, titanium isopropoxide, and titanium iodide;

in the case of Ta(V), the examples include tantalum butoxide, tantalum chloride, tantalum ethoxide, and tantalum methoxide;

in the case of Zr(IV), the examples include zirconium butoxide, zirconium ethoxide, zirconium isopropoxide, zirconium propoxide, zirconium tert-butoxide, and zirconium acetylacetonate;

in the case of Hf(IV), the examples include hafnium n-butoxide and hafnium tert-butoxide;

in the case of Mo(V), the examples include molybdenum isopropoxide and molybdenum trichloride isopropoxide;

in the case of W(V), the examples include tungsten ethoxide;

in the case of Zn(II), the examples include zinc citrate, zinc acetate, zinc acetylacetonate hydrate, zinc chloride, and zinc nitrate; and

in the case of Sn(IV), the examples tin acetate (IV), tin chloride (IV) dihydrate, and tin tert-butoxide (IV)

Some examples of a precursor of post-transition metals are as follows:

in the case of Al(III), the examples include aluminum ethoxide, aluminum isopropoxide, aluminum phenoxide, aluminum tert-butoxide, aluminum tributoxide, aluminum tri-sec-butoxide, aluminum chloride, and aluminum nitrate;

in the case of Ga(III), the examples include gallium acetylacetonate, gallium chloride, gallium fluoride, and gallium nitrate hydrate;

in the case of In(III), the examples include indium chloride, indium chloride tetrahydrate, indium fluoride, indium fluoride trihydrate, indium hydroxide, indium nitrate hydrate, indium acetate hydrate, indium acetylacetonate, and indium acetate; and

in the case of Tl(III), the examples include thallium acetate, thallium acetylacetonate, thallium chloride, thallium chloride tetrahydrate, thallium nitrate, and thallium nitrate trihydrate.

Some examples of a precursor of metalloids are as follows:

in the case of Ge(IV), the examples include germanium ethoxide, germanium isopropoxide, germanium methoxide, germanium(IV) chloride, and germanium(IV) bromide; and

in the case of Sb(III), the examples include antimony butoxide, antimony ethoxide, antimony methoxide, and antimony propoxide.

A sol-gel reaction of the organosilane, the silicate ester, and the oxide precursor described above may enable formation of various organic-inorganic composite materials. For example, an organic-inorganic composite coating layer formed of CaO—SiO₂, ZrO—SiO₂, MgO—SiO₂, Al₂O₃—SiO₂, TiO₂—SiO₂, ZnO₂—SiO₂, ZrO₂—SiO₂, Ga₂O₃—SiO₂, P₂O₅—SiO₂, P₂O₅—Na₂O—SiO₂, P₂O₅—Na₂O—Al₂O₃—SiO₂, P₂O₅—Al₂O₃—SiO₂, P₂O₅—CaO—Na₂O—SiO₂, B₂O₃—SiO₂, Na₂O—B₂O₃—SiO₂, GeO₂—SiO₂, and MoO₂—SiO₂ may be prepared. The principles and ways of the sol-gel reaction are well known in the art (for example, J. Am. Ceram. Soc. 71, 666˜672 (1988), J. Am. Chem. Soc. 133, 1917˜1934 (2011), Journal of Sol-Gel Science and Technology, 3, 219˜227 (1994), J. Mater. Chem., 15, 2134˜2140 (2005), Journal of Sol-Gel Science and Technology 13, 103˜107 (1998), J Sol-Gel Sci Techn (2006) 39:79˜83, Journal of Non-Crystalline Solids 100 (1988) 409˜412, Journal of Sol-Gel Science and Technology 37, 63˜68, 2006, J. Phys. Chem., B 1998, 102, 6465˜6470, and Catal Lett (2008) 126:286˜292).

The amount of organosilane in the organic-inorganic mixed solution may be determined according to the number of carbon atoms and the kind of the functional group in a silane organic functional group, to prevent cracking of the organic-inorganic composite coating layer and to provide flexibility to the layer. In some embodiments, the organic-inorganic mixed solution may be prepared by mixing components with amounts satisfying the equation of 0.001≦M_{organosilane}/(M_{silicate ester}+M_{other element})≦10, wherein M_{organosilane} is a molar number of organosilane, M_{silicate ester} is a molar number of silicate ester, and M_{other element} is a molar number of the other element of the oxide precursor. In another embodiment of the present invention, the amount of the organosilane may satisfy the relation of 0.1≦M_{organosilane}/(M_{silicate ester}+M_{other element})≦5.

Although the hybrid protective film 310 does not include inorganic silicon, the hybrid protective film 310 may perform protection function, and in this regard, M_{silicate} ester in the equation above may be 0. Here, the organic-inorganic mixed solution may be prepared by using only the organosilane, the other element, and water.

In general, the molar number of the other element (i.e., M_{other element}) may be the same as a molar number of the oxide precursor. However, when the molar number of the other element atoms in 1 mole oxide precursor is, like Li₂CO₃, an integer multiple of 1 (in the case that the oxide precursor is a non-stoichiometrical compound, a real multiple of 1), M_{other element} may be the corresponding integer multiple (i.e., the corresponding real value) of the molar number of the oxide precursor. For example, when the added oxide precursor is 2.5 mole Li₂CO₃, M_{other element} is 5. Likewise, various types of organosilane, silicate ester, and an oxide precursor are used together, M_{organosilane}, M_{silicate ester}, and M_{other element} are values obtained by adding corresponding chemical materials up.

When the amount of the organosilane is within this range, the organic-inorganic composite coating layer may be provided with flexibility, and in the subsequent step c), the plasma treatment may be adjusted within an appropriate period of time.

The amount of the oxide precursor of the other element in the organic-inorganic mixed solution may be determined according to a desired level of moisture and oxygen blocking characteristics and mechanical characteristics. In an embodiment of the present invention, components of the organic-inorganic mixed solution may be mixed in preparing the organic-inorganic mixed solution in such a way that the amount of the oxide precursor satisfies the relationship of 0.05≦M_{other element}/(M_{organosilane}+M_{silicate ester})≦20, wherein M_{organosilane} is a molar number of the organosilane, is a molar number of the silicate ester, and M_{other element} is a molar number of the other element of the oxide precursor. In another embodiment of the present invention, components of the organic-inorganic mixed solution may be mixed in preparing the organic-inorganic mixed solution in such a way that the amount of the oxide precursor satisfies the relationship of 0.05≦M_{other element}/(M_{organosilane}+M_{silicate ester})≦20 or the relationship of 0.1≦M_{other element}/(M_{organosilane}+M_{silicate ester})≦10.

M_{organosilane}, M_{silicate ester}, and M_{other element} are the same as defined with the previous relationship. When the oxide precursor of the other element is added at a ratio defined by the relationship with respect to silane components, the hybrid protective film 310 may not crack and may have excellent moisture and gas, including oxygen, blocking characteristics and mechanical strength.

Water included in the organic-inorganic mixed solution is a reactant for hydrolysis. Any water may be allowable as long as the water has sufficient purity, and may be, for example, distilled water or ultrapure water.

In some embodiments, an amount of water in the organic-inorganic mixed solution may be in a range of about 5 to about 350 parts by weight or about 10 to about 250 parts by weight, based on 100 parts by weight of a total weight of the organosilane and the oxide precursor (when silicate ester is included in the organic-inorganic mixed solution, based on 100 parts by weight of a total weight of the organosilane, the oxide precursor, and the silicate ester).

In some other embodiments, the molar number of water added in the organic-inorganic mixed solution may be equal to or higher than an equivalent with respect to a total molar number of hydrolyzable functional groups, such as an alkoxy group and an aryloxy group which are hydrolyzed in the organic-inorganic mixed solution.

In some other embodiments, in preparing the organic-inorganic mixed solution, the amounts of the water may be selected within a range that a ratio of a molar number of water to a molar number of hydrolyzable functional groups, such as an alkoxy group and an aryloxy group, of the organosilane and the silicate ester is in a range of 1:5 to 5:1, or 1:3 to 3:1. In this regard, when the oxide precursor also includes a hydrolyzable functional group, such as an alkoxy group and an aryloxy group, the molar number of the hydrolyzable functional group is a sum of the molar number of a hydrolyzable functional group of organosilane and silicate ester and the molar number of a hydrolyzable functional group of the oxide precursor.

To perform the sol-gel hydrolysis in step a), the organic-inorganic mixed solution may further include a solvent, in addition to water that is a reactant. As a solvent included in the organic-inorganic mixed solution, a polar solvent may be used. Some examples of a suitable polar solvent are alcohols, such as methanol, ethanol, isopropanol, butanol, 2-ethoxy-ethanol, 2-methoxy-ethanol, 2-buthoxy-ethanol, 1-methoxy-2-propanol, or 1-ethoxy-2-propanol; ketones, such as methylethylketone or methylisobutylketone; esters, such as ethyl acetate, butyl acetate, 2-ethoxy-ethyl acetate, 2-methoxy-ethyl acetate, or 2-buthoxy-ethyl acetate; an aromatic hydrocarbon, such as toluene or xylene; and N,N-dimethylmethaneamide as a polar solvent. These solvents may be used alone or in combination in the organic-inorganic mixed solution.

To promote the sol-gel hydrolysis and condensation reaction, an acid or a base catalyst may be used. As a catalyst that promotes hydrolysis, an acid, such as a hydrochloric acid, a nitric acid, a sulfuric acid, an acetatic acid, a hydrofluoric acid (HF), or an ammonia may be added to the polar solvent. The reaction time and temperature may vary according to the kinds of silane components and the oxide precursor, and their concentrations in the solvent. For example, the hydrolysis reaction may be performed under typical sol-gel hydrolysis and condensation reaction conditions of such silane components and the oxide precursor.

A sol solid content of the finally prepared organic-inorganic composite solution may be in a range of about 1 to about 50 wt %, for example, about 5 to about 30 wt % based on a solvent and water. When the amount of the silica sol is less than 5 wt %, a thickness is too small or even after a subsequent process, desired blocking characteristics may not be obtained. When the amount of the silica sol is greater than 50 wt %, the surface is rough and cracking may likely occur due to external impacts.

The obtained organic-inorganic composite coating solution, which is an organic-inorganic composite material sol, may be coated on the display unit 200 of the substrate 100 by various coating methods. In an embodiment of the present invention, the organic-inorganic composite coating solution may be coated by spin coating, dip coating, roll coating, screen coating, spray coating, spin casting, flow coating, screen printing, or ink-jetting.

In some embodiments, after the display unit 200 on the substrate 100 is coated with the organic-inorganic composite coating solution, an organic-inorganic composite layer is cured by thermal curing or photo curing. In some other embodiments, the organic-inorganic composite coating solution may be coated on the display unit 200 on the substrate 100 to a thickness after curing and treating in a range of about 0.1 μm to about 10 μm, or in a range of about 0.1 μm to about 5 μm.

Thermal curing may be performed at a temperature at which the OLED in the display unit 200 and the substrate 100 is not thermally deformed. The heat treatment conditions may vary according to the OLED and the substrate 100. The thermal curing may be performed at a temperature in a range of about 50° C. to about 200° C.

Photo curing may be performed as long as the organosilane of Formula 1 in which A¹, A², and A³ are unsaturated functional groups, such as a vinyl group, an acryl group, or a methacryl group, used as a source for the sol-gel hydrolysis reaction. When exposed to light, radicals are generated from organosilanes with such functional groups and the unsaturated functional groups are cross-linked. Accordingly, an organic-inorganic composite layer in which organic functional groups are cross-linked by irradiation to light may be formed. The photo curing may be performed by a typical photoinitiator, and examples of a suitable photoinitiator are, but are not limited thereto, 1-hydroxycyclohexylphenylketone (product name: Irgacure 184), benzophenone, 2-hydroxy-2-methylpropiophenone, 2,2-diethoxyacetophenone, and 3,3′,4,4′-tetra-(t-butylperoxycarbonyl)benzophenone. In this regard, the photoinitiator may be in a range of about 0.1 to about 6 parts by weight based on 100 parts by weight of the organic-inorganic composite coating solution.

In step c), without chemical deposition or sputtering under high vacuum, an upper surface of the organic-inorganic composite layer coated on the display unit 200 is treated with plasma, thereby converting organic-inorganic composite layer into the hybrid protective film 310. Due to the plasma treatment in step c), the inorganic part layer 313 is formed on the upper surface of the organic-inorganic composite layer, and the gradient part layer 312 is formed on a surface below the inorganic part layer 313. That is, the upper surface of the organic-inorganic composite layer containing a silane-derived organic functional group is plasma treated with a reactive gas to remove the organic functional group from the upper surface of the organic-inorganic composite layer to convert a portion of the upper surface of the organic-inorganic composite layer into a pure inorganic material layer, and furthermore, in a region of the organic-inorganic composite layer corresponding to the gradient part layer 312, a composition gradient of the organic functional group is formed in the depth direction to convert the organic-inorganic composite layer into the hybrid protective film 310 including the inorganic part layer 313, the gradient part layer 312, and the organic part layer 311.

The conversion of the upper surface of the organic-inorganic composite layer into the part layer of the inorganic material due to the plasma treatment in step c) is performed by simultaneous physical and chemical effects formed by plasma. Hereinafter, an operational principal of the method according to an embodiment of the present invention is to be described for ease of understanding. However, the present invention is not limited thereto. When a reactive gas (for example, oxygen) is used, due to chemical effects of plasma, an organic functional group present in a silicon chain in vicinity of the upper surface of the organic-inorganic composite layer decomposes and is removed therefrom in a gaseous form (CO, CO₂). Simultaneously, light energy with various wavelengths (soft X-ray, ultraviolet ray, visible ray, and infrared ray) generated during excitation-relaxation of gaseous molecules induced by plasma may cause a photochemical reaction at the surface of the organic-inorganic composite layer. In particular, when light with high energy, such as soft X-ray and vacuum ultraviolet ray (100 to 190 nm), is irradiated during the plasma treatment, Si—C, Si—O, and M-O bonds may decompose and radicals may be formed to realign molecules, thereby accelerating a cross-linking reaction. At the same time, since ions with high energy generated by the plasma treatment may induce pressure and heat during ion bombardment on a surface, a molecular structure in the treated surface region of the organic-inorganic composite layer is induced to have a dense structure.

Ultimately, due to the plasma treatment using a reactive gas, organic functional groups are effectively removed from the surface of the organic-inorganic composite layer to form the inorganic part layer 313 with a dense structure. Since the formed inorganic part layer 313 has a dense structure, excellent oxygen and moisture blocking effects may be obtained. The dense structure may be further enhanced due to an oxide of the other element. The inorganic part layer 313 with a dense structure has an increased surface hardness.

In addition, in a region below the inorganic part layer 313, the gradient part layer 312 is formed in which the organic functional group is not completely removed and a carbon concentration gradually increases in a thickness direction from the inorganic part layer 313 to the organic part layer 311.

In some embodiments, the plasma treatment in step c) may be continuously performed at once without any change in plasma treatment conditions during the plasma treatment. That is, in forming the gradient part layer 312, the organic-inorganic composite layer is continuously treated with plasma under constant treatment conditions without any change in plasma treatment conditions. By doing so, the hybrid protective film 310 having the compositionally gradient interface structure described above is formed. However, according to performance of the hybrid protective film 310, one of ordinary skill in the art may change plasma treatment conditions over time or may perform the plasma treatment intermittently several times.

The plasma surface treatment in step c) may be performed in such a way that the substrate 100 with the organic-inorganic composite layer on the display unit 200 in step b) is loaded into a plasma reaction chamber, a pressure of the chamber is decreased, a reactive gas (that is, a plasma source gas), such as O₂, N₂O, N₂, NH₃, H₂, and H₂O is supplied, and then, power is applied to an electrode to generate plasma to treat the surface of the organic-inorganic composite layer. In this regard, the plasma source gas supplied into the reaction chamber may be, in addition to a single gas, a mixed gas of O₂/N₂O, O₂/N₂, O₂/NH₃, O₂/H₂, Ar/O₂, He/O₂, Ar/N₂O, He/N₂O, Ar/NH₃, and He/NH₃, or a mixed gas including an inert gas, such as helium (He) or argon (Ar). In addition, as a power source for the generation of plasma, any one of various plasma power sources including a radiofrequency (RF) power source, a medium frequency (MF) power source, a direct current (DC) power source, and microwave (MW) power source may be used.

The thickness of the inorganic part layer 313 and the gradient part layer 312 may vary and moisture and oxygen blocking performance of each of the inorganic part layer 313 and the gradient part layer 312 formed by the plasma surface treatment in step c) may be controllable according to plasma output, a treatment pressure, a treatment time, and a distance between an electrode and a substrate, and a reactive gas. In general, the higher plasma output, the lower treatment pressure, and the longer treatment time, the more hydrocarbon component is removed, the greater thickness the inorganic part layer 313 and the gradient part layer 312, the higher moisture and oxygen blocking performance the hybrid protective 310 has. Although high plasma output may contribute to a decrease in the treatment time to obtain high moisture and oxygen blocking performance, due to the temperature increase resulting from the treatment, the OLED may be thermally deformed or the substrate 100 may be transformed. Accordingly, the plasma output and the treatment time need to be appropriately controlled. In addition, a bond, such as M-O or M-N (wherein M is silicon, or metal of the other element), may be formed according to a reactive gas and blocking characteristics may be controlled according to a reactive gas.

In some embodiments, to obtain excellent blocking characteristics, the inorganic part layer 313 may be formed to have a thickness in a range of about 10 nm to about 100 nm, or in a range of about 10 nm to about 50 nm. In another embodiment of the present invention, a total thickness of the inorganic part layer 313 and the gradient part layer 312 which are formed by the plasma treatment may be in a range of about 50 nm to about 250 nm, or in a range of about 100 nm to about 200 nm.

The formed hybrid protective film 310 has intermediate characteristics of an organic material and an inorganic material according to a ratio of the organic functional group. Accordingly, the organic part layer 311 may perform a buffering role between the display unit 200 formed below the organic part layer 311 and the inorganic part layer 313 formed by plasma treatment. Due to the buffering role, when an external force is applied to the hybrid protective film 310 or when the hybrid protective film 310 shrinks or expands due to temperature, a stress occurring at the interface is reduced and thus, cracks or exfoliation of the hybrid protective film 310 from the display unit 200 is suppressed.

In some other embodiments, when a radiofrequency (RF) power source is used as a plasma power source, a plasma treatment may be performed under conditions including a plasma output in a range of about 0.3 W/cm² to about 4 W/cm², a treatment time in a range of about 5 seconds to about 10 minutes, a pressure in a range of about 10 mtorr to about 500 mtorr. When the plasma output is less than 0.3 W/cm² the treatment time of 10 minutes or less is not sufficient to obtain a desired blocking performance, and when the plasma output is higher than 4 W/cm², the OLED or the substrate 100 may be damaged. In addition, when the plasma treatment pressure is greater than 500 mtorr or the treatment time is less than 5 seconds, a desired blocking performance may not be obtained.

According to methods described above, the hybrid protective film 310 may be formed on the counter electrode 225. When compared to a typical thin-film encapsulation method, the hybrid protective film 310 including the organic part layer 311, the gradient part layer 312, and the inorganic part layer 313 is formed by forming an organic-inorganic composite layer and treating a plasma surface treatment thereto. In this regard, the methods described above are much simplified than the thin-film encapsulation method requiring deposition processes multiple times. In addition, in the thin-film encapsulation method, exfoliation between layers may occur, and due to differences in properties of each layer, cracks may occur in response to a rapid temperature change or external impacts. However, since the hybrid protective film 310 of the present invention do not have clearly distinguishable interfaces between each of the part layers, exfoliation between each of the part layers do not occur. In addition, since the properties of the hybrid protective film 310 are gradually changed according to the thickness of thereof, cracks do not occur in response to external impacts or temperature changes. If necessary, by changing the plasma treatment conditions, properties of the hybrid protective film 310 may be easily adjusted.

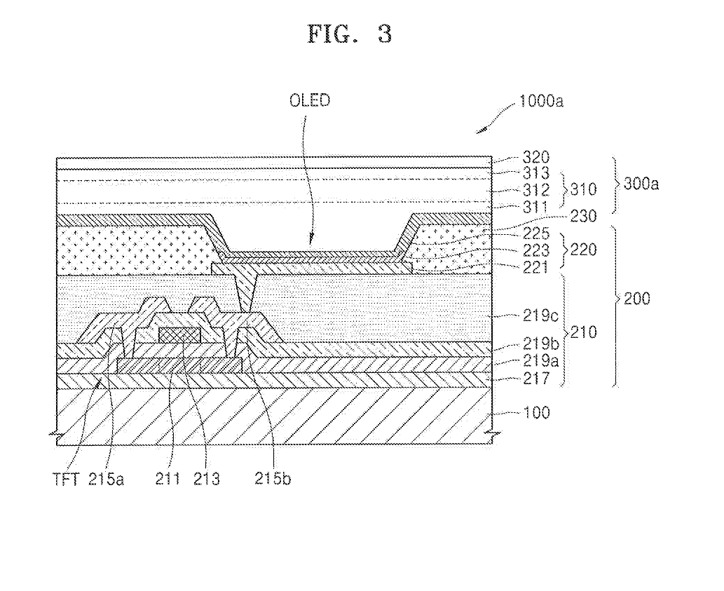

FIG. 3 is a schematic cross-sectional view of a pixel region in the organic light-emitting display apparatus according to another of the present invention.

Referring to FIG. 3, an organic light-emitting display apparatus 1000a in which the hybrid protective film 310 and an inorganic barrier layer 320 are disposed on the display unit 200 is illustrated.

The organic light-emitting display apparatus 1000a is substantially similar with the organic light-emitting display apparatus 1000 of FIG. 2, except that the inorganic barrier layer 320 is further disposed on the hybrid protective film 310. Descriptions of the substrate 100, the display unit 200, and the hybrid protective film 310 included in the organic light-emitting display apparatus 1000a are already described in connection with FIG. 2, and thus, the same descriptions will not be repeated herein.

The inorganic barrier layer 320 may be disposed on the inorganic part layer 313 of the hybrid protective film 310, and the inorganic barrier layer 320 may include at least one inorganic material selected from the group consisting of silicon oxide, silicon nitride, silicon nitroxide, aluminum oxide, aluminum nitride, titanium oxide, or titanium nitride, and zirconium oxide. For example, the inorganic barrier layer 320 may include at least one of silicon nitride (SiNₓ), aluminum oxide (Al₂O₃), silicon oxide (SiO₂), titanium oxide (TiO₂), and zirconium oxide (ZrO₂). Materials for the inorganic barrier layer 320 may be selected in consideration of adhesion to the inorganic part layer 313 located below the inorganic barrier layer 320.

Referring to FIG. 3, the inorganic barrier layer 320 is illustrated as if it is a single layer, but is an exemplary embodiment. That is, inorganic barrier layer 320 may have a stack structure of a plurality of layers. For example, the inorganic barrier layer 320 may have a stack structure of silicon oxide (SiO₂)/aluminum oxide (Al₂O₃)/silicon oxide(SiO₂).

The inorganic barrier layer 320 may be formed by using various deposition methods, such as chemical vapor deposition (CVD), PECVD, high density plasma CVD (HDP-CVD), sputtering, and atomic layer deposition (ALD).

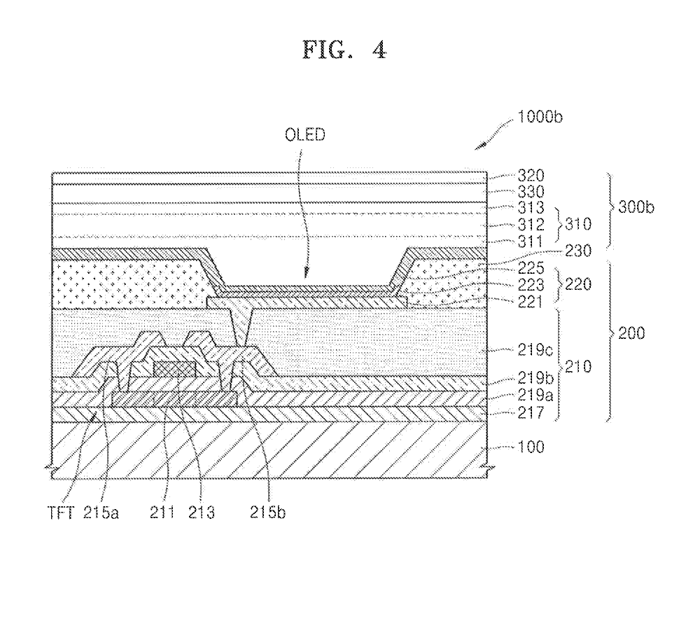

FIG. 4 is a schematic cross-sectional view of a pixel region in the organic light-emitting display apparatus according to another embodiment of the present invention

Referring to FIG. 4, an organic light-emitting display apparatus 1000b in which the hybrid protective film 310, the organic-inorganic composite layer 330, and an inorganic barrier layer 320 are disposed on the display unit 200 is illustrated.

The organic light-emitting display apparatus 1000b is substantially similar with the organic light-emitting display apparatus 1000a of FIG. 3, except that the organic-inorganic composite layer 330 is further disposed between the hybrid protective film 310 and the inorganic barrier layer 320. Descriptions of the substrate 100, the display unit 200, the hybrid protective film 310, and the inorganic barrier layer 320 included in the organic light-emitting display apparatus 1000b are already described in connection with FIGS. 2 and 3, and thus, the same descriptions will not be repeated herein.

The organic-inorganic composite layer 330 may be disposed between the hybrid protective film 310 and the inorganic barrier layer 320. The hybrid protective film 310 is formed by performing a plasma treatment to a surface of an organic-inorganic composite layer as described above. However, the organic-inorganic composite layer 330 is identical to the organic-inorganic composite layer formed before the hybrid protective film 310 is formed by performing the plasma surface treatment thereto. That is, the organic-inorganic composite layer 330 may be formed by coating and curing the hybrid protective film 310 with the organic-inorganic composite coating solution that is prepared by sol-gel hydrolysis and condensation with respect to the organic-inorganic mixed solution. In this regard, the organic part layer 311 of the hybrid protective film 310 is not affected by the plasma surface treatment, and thus, the organic part layer 311 may have characteristics and compositions that are substantially similar with those of the organic-inorganic composite layer 330.

The organic-inorganic composite layer 330 may relieve internal stress of the inorganic part layer 313 as being disposed on the inorganic part layer 313 of the hybrid protective film 310, and accordingly, defects such as microcracks that may occur in the inorganic part layer 313 may be compensated.

Referring to FIG. 4, an encapsulation unit 300b is illustrated as if it includes the hybrid protective film 310, the organic-inorganic composite layer 330, and the inorganic barrier layer 320, but in some embodiments, the encapsulation unit 300b may only include the hybrid protective film 310 and the organic-inorganic composite layer 330 and exclude the inorganic barrier layer 320.

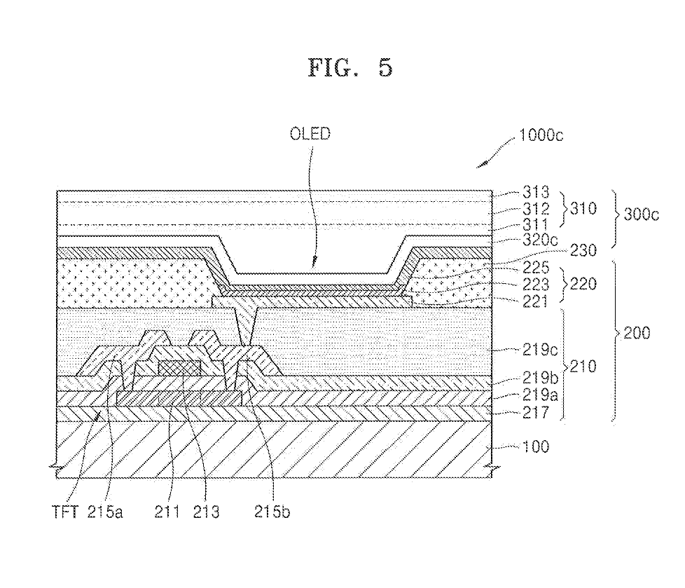

FIG. 5 is a schematic cross-sectional view of a pixel region in the organic light-emitting display apparatus according to another embodiment of the present invention

Referring to FIG. 5, an organic light-emitting display apparatus 1000c in which an inorganic barrier layer 320c and the hybrid protective film 310 on the display unit 200 is illustrated.

The organic light-emitting display apparatus 1000c is substantially similar with the organic light-emitting display apparatus 1000 of FIG. 2, except that the inorganic barrier layer 320c is further disposed between the hybrid protective film 310 and the display unit 200. Descriptions of the substrate 100, the display unit 200, and the hybrid protective film 310 included in the organic light-emitting display apparatus 1000c are already described in connection with FIG. 2, and thus, the same descriptions will not be repeated herein. In addition, the inorganic barrier layer 320c of the organic light-emitting display apparatus 1000c is substantially similar with the inorganic barrier layer 320 of the organic light-emitting display apparatus 1000a of FIG. 3, except a location on which the inorganic barrier layer 320c is disposed.

The inorganic barrier layer 320c may be disposed on the counter electrode 225 of the display unit 200. The inorganic barrier layer 320c may include, for example, at least one of silicon nitride (SiNₓ), aluminum oxide (Al₂O₃), silicon oxide (SiO₂), titanium oxide (TiO₂), and zirconium oxide (ZrO₂), and may be formed in a single layer or a multilayer. In addition, the inorganic barrier layer 320c may be formed by using various deposition methods, such as CVD, PECVD, HDP-CVD, sputtering, and ALD.

Although not illustrated in FIG. 5, a halogenated metal layer including LiF may be additionally disposed between the inorganic barrier layer 320c and the counter electrode 225. The halogenated metal layer may prevent damage to the display unit 200 when the inorganic barrier layer 320c is formed.

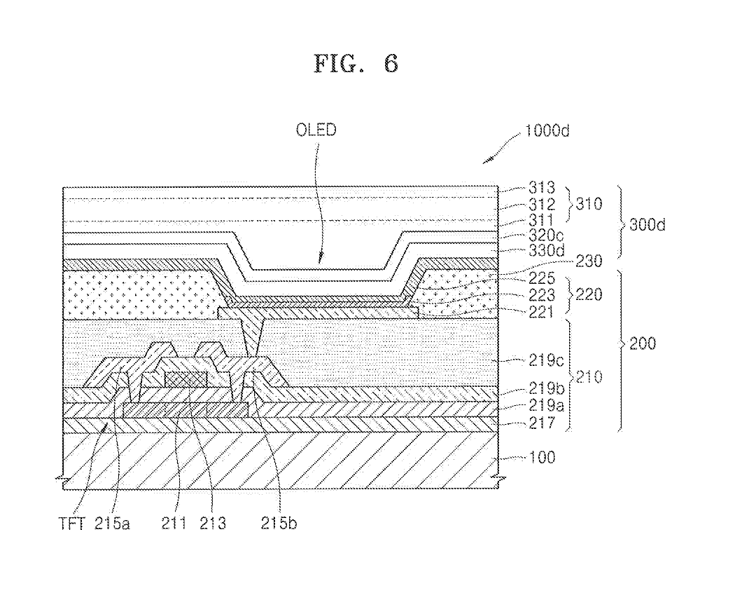

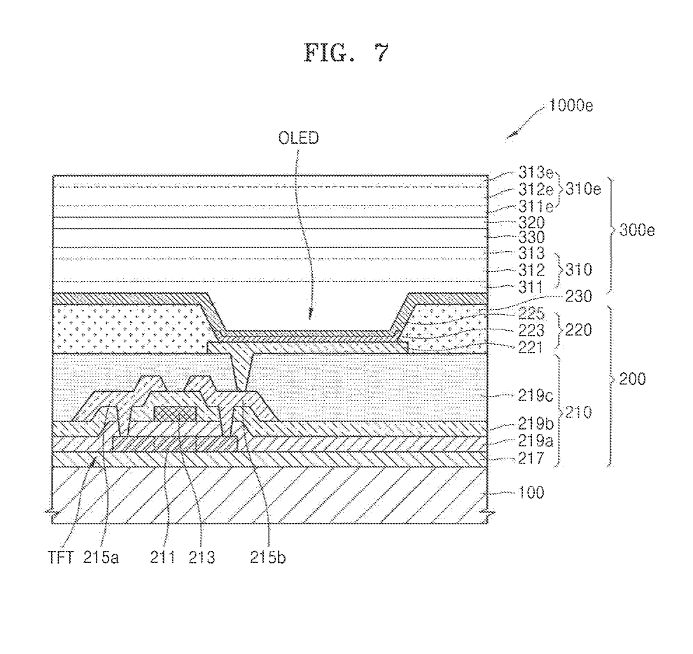

FIG. 6 is a cross-sectional view schematically illustrating another pixel region of the organic light-emitting display apparatus.

Referring to FIG. 6, an organic light-emitting display apparatus 1000d in which an organic-inorganic composite layer 330d, the inorganic barrier layer 320c, and the hybrid protective film 310 are disposed on the display unit 200 is illustrated.

The organic light-emitting display apparatus 1000d is substantially similar with the organic light-emitting display apparatus 1000c of FIG. 5, except that the organic-inorganic composite layer 330d is additionally disposed between the inorganic barrier layer 320c and the display unit 200. Descriptions of the substrate 100, the display unit 200, and the hybrid protective film 310 included in the organic light-emitting display apparatus 1000d are already described in connection with FIG. 2, and thus, the same descriptions will not be repeated herein. In addition, the inorganic barrier layer 320c of the organic light-emitting display apparatus 1000d substantially similar with the inorganic barrier layer 320 of the organic light-emitting display apparatus 1000a of FIG. 3, except a location on which the inorganic barrier layer 320c is disposed. In addition, the organic-inorganic composite layer 330d of the organic light-emitting display apparatus 1000d substantially similar with the organic-inorganic composite layer 330d of the organic light-emitting display apparatus 1000b of FIG. 4, except a location on which the organic-inorganic composite layer 330d is disposed.

The organic-inorganic composite layer 330d may be disposed on the counter electrode 225 of the display unit 200. The organic-inorganic composite layer 330d may be formed by coating and curing on the counter electrode 225 of the display unit 200 with the organic-inorganic composite coating solution that is prepared by sol-gel hydrolysis and condensation with respect to the organic-inorganic mixed solution.

The inorganic barrier layer 320c may be disposed on the organic-inorganic composite layer 330d. The inorganic barrier layer 320c may include, for example, at least one of silicon nitride (SiNₓ), aluminum oxide (Al₇O₃), silicon oxide (SiO₂), titanium oxide (TiO₂), and zirconium oxide (ZrO₂), and may be formed in a single layer or a multilayer. In addition, the inorganic barrier layer 320c may be formed by using various deposition methods, such as CVD, PECVD, HDP-CVD, sputtering, and ALD.

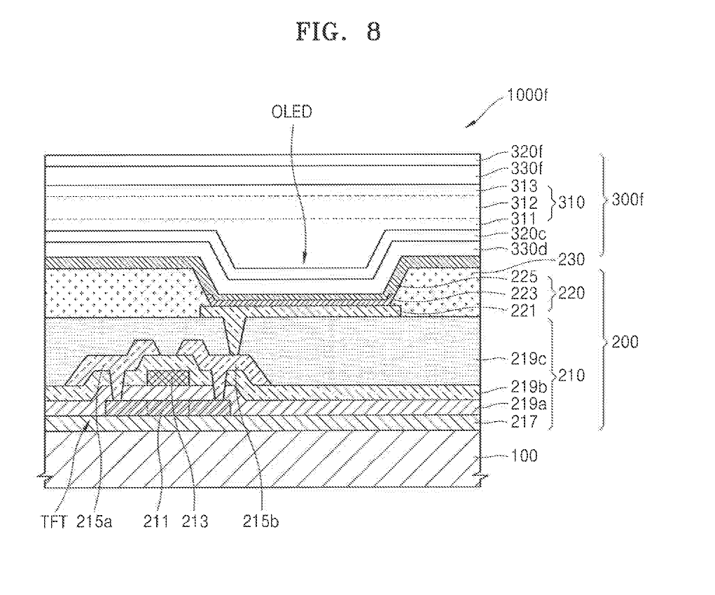

FIG. 7 is a schematic cross-sectional view of a pixel region in the organic light-emitting display apparatus according to another embodiment of the present invention.

Referring to FIG. 7, an organic light-emitting display apparatus 1000e in which a lower hybrid protective film 310, the organic-inorganic composite layer 330, the inorganic barrier layer 320, and an upper hybrid protective film 310e are disposed on the display unit 200 is illustrated.

The organic light-emitting display apparatus 1000e is substantially similar with the organic light-emitting display apparatus 1000b of FIG. 4, except that the upper hybrid protective film 310e is additionally provided. Descriptions of the substrate 100, the display unit 200, the lower hybrid protective film 310, the organic-inorganic composite layer 330, and the inorganic barrier layer 320 included in the organic light-emitting display apparatus 1000e are already described in connection with FIGS. 2 to 4, and thus, the same descriptions will not be repeated herein. The lower hybrid protective film 310 of FIG. 7 is merely named differently from the hybrid protective film 310 of FIG. 4, but they are substantially the same each other.

The upper hybrid protective film 310e may be disposed on the inorganic barrier layer 320. The upper hybrid protective film 310e is merely disposed on a different location from that of the lower hybrid protective film 310, and they have substantially the same characteristics and compositions each other.

The upper hybrid protective film 310e may be formed by coating, curing, and performing a plasma surface treatment on the inorganic barrier layer 320 with the organic-inorganic composite coating solution that is prepared by sol-gel hydrolysis and condensation with respect to the organic-inorganic mixed solution. Due to the plasma surface treatment, the upper hybrid protective film 310e may also include the organic part layer 311e, the gradient part layer 312e, and the inorganic part layer 313e in the same manner.

In this regard, the organic part layer 311e is not affected by the plasma surface treatment, and accordingly, may contain carbon in a predetermined amount. In the inorganic part layer 313e, carbon is not detected since carbon is removed by the plasma surface treatment. Due to the plasma surface treatment partially performed on the gradient part layer 312e, the gradient part layer 312e decreases an amount of carbon as being more contiguous to the inorganic part layer 313e.

FIG. 8 is a schematic cross-sectional view of a pixel region in the organic light-emitting display apparatus according to another embodiment of the present invention.

Referring to FIG. 8, an organic light-emitting display apparatus 1000f in which a lower organic-inorganic composite layer 330d, a lower inorganic barrier layer 320c, the hybrid protective film 310, an upper organic-inorganic composite layer 330f, and an upper inorganic barrier layer 320f are disposed on the display unit 200 is illustrated.

The organic light-emitting display apparatus 1000f is substantially similar with the organic light-emitting display apparatus 1000d of FIG. 6, except that the upper organic-inorganic composite layer 330f and the upper inorganic barrier layer 320f are additionally disposed on the hybrid protective film 310. Descriptions of the substrate 100, the display unit 200, the lower organic-inorganic composite layer 330d, the lower inorganic barrier layer 320c, and the hybrid protective film 310 included in the organic light-emitting display apparatus 1000f are already described in connection with FIGS. 2 to 6, and thus, the same descriptions will not be repeated herein. The lower organic-inorganic composite layer 330d and the lower inorganic barrier layer 320c of FIG. 8 are merely named differently from each other and they may have substantially the same as the organic-inorganic composite layer 330d and the inorganic barrier layer 320c of FIG. 6.

The upper organic-inorganic composite layer 330f and the upper inorganic barrier layer 320f may be each substantially the same as the lower organic-inorganic composite layer 330d and the lower inorganic barrier layer 320c, except a location on which each layer is disposed.

The upper organic-inorganic composite layer 330f may be disposed on the hybrid protective film 310. The upper organic-inorganic composite layer 330f may be formed by coating and curing on the hybrid protective film 310 with the organic-inorganic composite coating solution that is prepared by sol-gel hydrolysis and condensation reaction with respect to the organic-inorganic mixed solution. Materials for the upper organic-inorganic composite layer 330f and materials for the lower organic-inorganic composite layer 330d may be the same or different each other.

The upper inorganic barrier layer 320f may be disposed on the organic-inorganic composite layer 330f. The inorganic barrier layer 320f may include, for example, at least one of silicon nitride (SiNₓ), aluminum oxide (Al₂O₃), silicon oxide(SiO₂), titanium oxide (TiO₂), and zirconium oxide (ZrO₂), and may be formed in a single layer or a multilayer. In addition, the upper inorganic barrier layer 320f may be formed by using various deposition methods, such as CVD, PECVD, HDP-CVD, sputtering, and ALD. Materials for the upper inorganic barrier layer 320f and materials for the lower inorganic barrier layer 320c may be the same or different each other.

The organic light-emitting display apparatus 1000 of FIG. 2 was manufactured by inventors of the present invention as follows:

A) The display unit 200 was formed on the substrate 100,

wherein a polyethylene terephthalate (PET) film, which is transparent plastic, having a thickness of 125 μm was used as the substrate 100, and

wherein the display unit 200 included on the substrate 100, a TFT, the pixel electrode 221 connected to the TFT, the pixel define layer 230 exposing a part of the pixel electrode 221, the interlayer 223 including an organic light-emitting layer that was disposed on a part of the exposed pixel electrode 221, and the counter electrode 225 disposed on the interlayer 223.

B) An organic-inorganic mixed solution was prepared to form an organic-inorganic composite layer on the display unit 200,

wherein 1.25 g (6 mmol) of tetraethyl orthosilicate (TEOS) and 1.07 g (6 mmol) methyltriethoxysilane (MTES) were added to 12 mL of isopropanol solvent to prepare an organic-inorganic mixed solution. The prepared organic-inorganic mixed solution was subjected to sol-gel hydrolysis and condensation to prepare a sol-type organic-inorganic composite coating solution, and

wherein the organic-inorganic composite coating solution was spin-coated to a thickness of about 2 μm to about 3 μm to cover the display unit 200 on the substrate 100. Then, the organic-inorganic composite layer was formed by curing the display unit 200.

C) A surface of the organic-inorganic composite layer as treated with plasma to form the hybrid protective film 310,

wherein the substrate 100 on which the organic-inorganic composite layer was formed on display unit 200 was placed in a plasma reaction chamber, and the pressure in the chamber was decreased to 10⁻³ torr or less by using a vacuum pump. Oxygen gas was added to the chamber while the vacuum pump continuously operated so that plasma is generated at a pressure of 50 mtorr and an RF output of 2 W/cm² to treat a surface of the organic-inorganic composite layer for 1 minute, thereby removing hydrocarbon existing on or near the surface of the organic-inorganic composite layer.

As a result, the organic-inorganic composite layer was converted into the hybrid protective film 310 including the inorganic part layer 313 where carbon was removed, the organic part layer 311 where carbon was contained in a predetermined amount, and the gradient part layer 312 disposed between the inorganic part layer 313 and the organic part layer 311 and increasing an amount of carbon as being more contiguous to the organic part layer 311.

The encapsulation unit 300 of the organic light-emitting display apparatus 1000 including the hybrid protective film 310 had a water vapor transmission rate of 15×10⁻³ g/m²/day when measured by Mocon Permatran-W (Model 3/33) under conditions of 37.8° C. and relative humidity of 100%, and in addition, had a light transmittance of 88.5% when measured by UV-Vis Spectrometer HP 8453 with respect to light having a wavelength of 550 nm.

The organic light-emitting display apparatus 1000a of FIG. 3 was manufactured by inventors of the present invention as follows:

The steps A) to C) described above were performed in the same manner.

D) The inorganic barrier layer 320 was formed on the hybrid protective film 310,

wherein the substrate 100 on which the hybrid protective film 310 was formed on the display unit 200 was placed in a plasma reaction chamber, and the pressure in the chamber was decreased to 10⁻⁶ torr or less by using a vacuum pump. Argon gas was added to the chamber while the vacuum pump continuously operated so that plasma occurs at a pressure of 1 mtorr and an RF output of 5 W/cm². Collision with a target silicon oxide occurred by argon gas, which was ionized by plasma generated therein and was accelerated toward electrodes, thereby emitting silicon oxide (SiOₓ). The inorganic barrier layer 320 formed of the emitted silicon oxide (SiOₓ) was then layered over the hybrid protective film 310. Here, the inorganic barrier layer 320 had a thickness in a range of about 30 nm to about 120 nm.

The encapsulation unit 300 of the organic light-emitting display apparatus 1000a including the hybrid protective film 310 and the organic barrier layer 320 had a water vapor transmission rate of 9×10⁻³ g/m²/day when measured by Mocon Permatran-W (Model 3/33) under conditions of 37.8° C. and relative humidity of 100%, and in addition, had a light transmittance of 88.7% when measured by UV-Vis Spectrometer HP 8453 with respect to light having a wavelength of 550 nm.

The organic light-emitting display apparatus 1000b shown in FIG. 4 was manufactured by inventors of the present invention as follows:

The steps A) to C) described above were performed in the same manner.

In the step D) prior to the step E), the organic-inorganic composite layer 330 was formed on a hybrid protective film 310,

wherein the organic-inorganic composite layer 330 was formed by curing the sol-type organic-inorganic composite coating solution prepared in the step B above. The hybrid protective film 310 was spin-coated and cured with the organic-inorganic composite coating solution, thereby forming the organic-inorganic composite layer 330.

In the same manner as in step D) above, an inorganic barrier layer 320 was formed on the organic-inorganic composite layer 330.

The encapsulation unit 300b of the organic light-emitting display apparatus 1000b including the hybrid protective film 310, the organic-inorganic composite layer 330, and the inorganic barrier layer 320 had a water vapor transmission rate of 5×10⁻³ g/m²/day or less when measured by Mocon Permatran-W (Model 3/33) under conditions of 37.8° C. and relative humidity of 100%, and in addition, had a light transmittance of 88.5% when measured by UV-Vis Spectrometer HP 8453 with respect to light having a wavelength of 550 nm. Here, the encapsulation unit 300b had a water vapor transmission rate at a level less than detection limit.

The organic-inorganic composite layer 330 was deemed to improve barrier performance thereof by filling up microcracks that may exist on the inorganic barrier layer 320.

The organic light-emitting display apparatus 1000c of FIG. 5 was manufactured by inventors of the present invention as follows:

The step A) described above was performed in the same manner.

Prior to the step B), the step D) was performed.

The steps B) and C) were performed, thereby forming the encapsulation unit 300c including the inorganic barrier layer 320c and the hybrid protective film 310 on the display unit 200.

The encapsulation unit 300c of the organic light-emitting display apparatus 1000c had a water vapor transmission rate of less than 5×10⁻³ g/m²/day when measured by Mocon Permatran-W (Model 3/33) under conditions of 37.8° C. and relative humidity of 100%, and in addition, had a light transmittance of 86.3% when measured by UV-Vis Spectrometer HP 8453 with respect to light having a wavelength of 550 nm. Here, the Mocon Permatran-W (Model 3/33) had detection limit of 5×10⁻³ g/m²/day, and in this regard, the encapsulation unit 330c had a water vapor transmission rate at a level less than detection limit.

The organic light-emitting display apparatus 1000d of FIG. 6 was manufactured by inventors of the present invention as follows:

The steps A), E), and D) described above were sequentially performed in the same manner.

The steps B) and C) were performed, thereby forming the encapsulation unit 300d including the organic-inorganic composite layer 330d, the inorganic barrier layer 320c, and the hybrid protective film 310 on the display unit 200.

The encapsulation unit 300d of the organic light-emitting display apparatus 1000d had a water vapor transmission rate of less than 5×10⁻³ g/m²/day when measured by Mocon Permatran-W (Model 3/33) under conditions of 37.8° C. and relative humidity of 100%, and in addition, had a light transmittance of 87.5% when measured by UV-Vis Spectrometer HP 8453 with respect to light having a wavelength of 550 nm. Here, the Mocon Permatran-W (Model 3/33) had detection limit of 5×10⁻³ g/m²/day, and in this regard, the encapsulation unit 330d had a water vapor transmission rate at a level less than detection limit.

The organic light-emitting display apparatus 1000e of FIG. 7 was manufactured by inventors of the present invention as follows:

The steps A) to C), E), and ED) described above were sequentially performed in the same manner.

The steps B) and C) were performed again, thereby forming the encapsulation unit 300e including the lower hybrid protective film 310, the organic-inorganic composite layer 330d, the inorganic barrier layer 320c, and the upper hybrid protective film 310e on the display unit 200.

The encapsulation unit 300e of the organic light-emitting display apparatus 1000e had a water vapor transmission rate of less than 5×10³ g/m²/day when measured by Mocon Permatran-W (Model 3/33) under conditions of 37.8° C. and relative humidity of 100%, and in addition, had a light transmittance of 85.2% when measured by UV-Vis Spectrometer HP 8453 with respect to light having a wavelength of 550 nm. Here, the Mocon Permatran-W (Model 3/33) had detection limit of 5×10⁻³ g/m²/day, and in this regard, the encapsulation unit 330e had a water vapor transmission rate at a level less than detection limit.

The organic light-emitting display apparatus 1000f of FIG. 8 was manufactured by inventors of the present invention as follows:

The steps A), E), and D) described above were sequentially performed in the same manner.

The steps B) and C) were performed again, followed by performing the steps E) and D) again, thereby forming the encapsulation unit 300f including the lower organic-inorganic composite layer 330d, the lower inorganic barrier layer 320c, the hybrid protective film 310, the upper organic-inorganic composite layer 330f, and the upper inorganic barrier layer 320f on the display unit 200.

The encapsulation unit 300f of the organic light-emitting display apparatus 1000f had a water vapor transmission rate of less than 5×10⁻³ g/m²/day when measured by Mocon Permatran-W (Model 3/33) under conditions of 37.8° C. and relative humidity of 100%, and in addition, had a light transmittance of 85.5% when measured by UV-Vis Spectrometer HP 8453 with respect to light having a wavelength of 550 nm. Here, the Macon Permatran-W (Model 3/33) had detection limit of 5×10⁻³ g/m²/day, and in this regard, the encapsulation unit 330f had a water vapor transmission rate at a level less than detection limit.

The organic light-emitting display apparatuses 1000 to 1000f had water vapor transmission rates and light transmittances as shown in Table 1 below.

TABLE 1

| | Water vapor | Light | MOCON |
|---|---|---|---|
| Structure of | transmission rate | transmittance | detection limit |
| encapsulation unit | (g/m²/day) | (%, 550 nm) | (g/m²/day) |
| 300 (HP) | 15 × 10⁻³ | 88.5 | 5 × 10⁻³ |
| 300a (IB/HP) | 9 × 10⁻³ | 88.7 | 5 × 10⁻³ |
| 300b (IB/OIC/HP) | Less than | 88.5 | 5 × 10⁻³ |
| | detection limit | | |
| 300c (HP/IB) | Less than | 86.3 | 5 × 10⁻³ |
| | detection limit | | |
| 300d (HP/IB/OIC) | Less than | 87.5 | 5 × 10⁻³ |
| | detection limit | | |
| 300e (HP/IB/OIC/HP) | Less than | 85.2 | 5 × 10⁻³ |
| | detection limit | | |
| 300f | Less than | 85.5 | 5 × 10⁻³ |
| (IB/OIC/HP/IB/OIC) | detection limit | | |
| 300b′ (OIC/HP) | Less than | 89.3 | 5 × 10⁻³ |
| | detection limit | | |

Here, HP represents the hybrid protective film 310, IB represents the inorganic barrier layer, and OIC represents the organic-inorganic composite layer. According to modified embodiments of the present invention, the encapsulation unit 300b′ had a structure in which the formation of the inorganic barrier layer was omitted in the encapsulation unit 300b. The water vapor transmission rates were measured under conditions of 37.8° C. and relative humidity of 100%. The Mocon Permatran-W (Model 3/33) was used for the measurement, wherein detection limit thereof was 5×10⁻³ g/m²/day

As comparative embodiments, the water vapor transmission rates were measured with respect to structures in which the hybrid protective film was not included in the encapsulation unit.

In the case of the encapsulation unit including the organic-inorganic composite layer or in the case of the encapsulation unit including the inorganic barrier layer and organic-inorganic composite layer, the organic light-emitting display apparatus had a water vapor transmission rate exceeding 10⁻¹ g/m²/day.

In the case of the encapsulation unit formed of the inorganic barrier layer having a thickness of 25 nm, the organic light-emitting display apparatus had a water vapor transmission rate 0.59 g/m²/day.

In the case of the encapsulation unit formed of the inorganic barrier layer having a thickness of 60 nm, the organic light-emitting display apparatus had a water vapor transmission rate of 0.27 g/m²/day.

In the case of the encapsulation unit formed of the inorganic barrier layer having a thickness of 115 nm, the organic light-emitting display apparatus had a water vapor transmission rate of 0.35 g/m²/day.

In the case of the encapsulation unit formed of the inorganic barrier layer and the organic-inorganic composite layer having a thickness of 60 nm, the organic light-emitting display apparatus had a water vapor transmission rate of 0.37 g/m²/day.

According to one or more embodiments of the present invention, an organic light-emitting display apparatus and a method of manufacturing the same may be achieved to manufacture an organic light-emitting display apparatus including a hybrid protective film with high moisture and oxygen blocking performance in a simple manufacturing process. In addition, the organic light-emitting display apparatus according to one or more embodiments of the present invention may have a minimum thickness, and accordingly, manufacturing cost thereof may be reduced.

It should be understood that the exemplary embodiments described therein should be considered in a descriptive sense only and not for purposes of limitation. Descriptions of features or aspects within each embodiment should typically be considered as available for other similar features or aspects in other embodiments.

While one or more embodiments of the present invention have been described with reference to the figures, it will be understood by those of ordinary skill in the art that various changes in form and details may be made therein without departing from the spirit and scope of the present invention as defined by the following claims.

What is claimed is:

1. An organic light-emitting display apparatus comprising:
a substrate;
a display unit disposed on the substrate and comprising an organic light-emitting device (OLED); and
an encapsulation unit comprising a hybrid protective film for encapsulating the display unit;
wherein the hybrid protective film comprises an inorganic part layer where carbon is removed, an organic part layer where carbon is contained in a predetermined amount, and a gradient part layer disposed between the inorganic part layer and the organic part layer and increasing an amount of carbon as being more contiguous to the organic part layer.

2. The organic light-emitting display apparatus of claim 1, wherein the display unit comprises:
a thin film transistor (TFT) on the substrate;
a pixel electrode connected to the TFT;
a pixel define layer exposing at least a part of the pixel electrode and defining an emission region;
an organic light-emitting layer disposed on the at least a part of the pixel electrode that is exposed by the pixel define layer; and
a counter electrode disposed on the organic light-emitting layer and the pixel define layer.

3. The organic light-emitting display apparatus of claim 2, wherein the inorganic part layer and the gradient part layer each have a predetermined thickness, and the organic part layer is disposed thicker on the organic light-emitting layer than on the pixel define layer.

4. The organic light-emitting display apparatus of claim 1, wherein the encapsulation unit is disposed on the hybrid protective film, and further comprises an inorganic barrier layer including an inorganic material.

5. The organic light-emitting display apparatus of claim 1, wherein the encapsulation unit further comprises an organic-inorganic composite layer disposed on the hybrid protective film, and the hybrid protective film is formed by performing a plasma surface treatment on a layer that is formed of the same material as that of the organic-inorganic composite layer.

6. The organic light-emitting display apparatus of claim 5, wherein the encapsulation unit is disposed on the organic-inorganic composite layer and further comprises an inorganic barrier layer including an inorganic material.

7. The organic light-emitting display apparatus of claim 6, wherein the encapsulation further comprises an upper protective hybrid protective film disposed on the inorganic barrier layer and having a part layer structure that is the same as that of the hybrid protective film.

8. The organic light-emitting display apparatus of claim 1, wherein the encapsulation unit further comprises an inorganic barrier layer disposed between the display unit and the hybrid protective film and including an inorganic material.

9. The organic light-emitting display apparatus of claim 8, wherein the encapsulation unit further comprises an organic-inorganic composite layer disposed between the display unit and the inorganic barrier layer,
and the hybrid protective film is formed by performing a plasma surface treatment on a layer that is formed of the same material as that of the organic-inorganic composite layer.

10. The organic light-emitting display apparatus of claim 9, wherein the encapsulation unit further comprises an upper organic-inorganic composite layer disposed on the hybrid protective film and including a material that is the same as that of the organic-inorganic composite layer; and
an upper inorganic barrier layer disposed on the upper organic-inorganic composite layer and including an inorganic material.

11. The organic light-emitting display apparatus of claim 1, wherein the hybrid protective film has a skeleton of a network structure including —O—Si—O— linkages,
and the network structure comprises silicon, oxygen, hydrogen, and carbon,
wherein some silicon atoms are directly bonded to carbon atoms that constitute a part of an organic functional group by covalent bond.

12. The organic light-emitting display apparatus of claim 11, wherein the network structure further comprises at least one other element,
wherein the other element is at least one selected from alkali metal, alkali earth metal, transition metal, post-transition metal, metalloid, boron, and phosphorous, and
wherein the other element exists in an oxide form in an interstitial location inside the network structure, or is linked to a silicon atom constituting the skeleton of the network structure by the covalent bond of other element-oxygen-silicon form.

13. The organic light-emitting display apparatus of claim 12, wherein amounts of silicon and other element in the hybrid protective film change within ±10 wt % in a thickness direction of the hybrid protective film.

14. The organic light-emitting display apparatus of claim 1, wherein the encapsulation unit has a water vapor transmission rate of 0.015 g/m²/day or less at a temperature of 37.8° C. and a relative humidity of 100%, and has a light transmission rate of 85% or more with respect to light having a wavelength of 550 nm at a temperature of 25° C.

15. An organic light-emitting display apparatus comprising:
a flexible substrate;
a display unit disposed on the flexible substrate and comprising an organic light-emitting device (OLED); and
an encapsulation unit encapsulating an upper surface and side surfaces of the display unit,
wherein the encapsulation unit comprises a hybrid protective film including an inorganic part layer where carbon is removed, an organic part layer where carbon is contained in a predetermined amount, and a gradient part layer disposed between the inorganic part layer and the organic part layer and increasing an amount of carbon as being more contiguous to the organic part layer, and
at least one of an inorganic barrier layer including an inorganic material and an organic-inorganic composite layer including a material that is the same as that of the organic part layer, and
wherein the encapsulation unit has a water vapor transmission rate of 0.009 g/m²/day or less at a temperature of 37.8° C. and a relative humidity of 100%.

16. A method of manufacturing an organic light-emitting display apparatus, the method comprising:
forming a display unit including an organic light-emitting device (OLED) on a substrate;
preparing an organic-inorganic composite coating solution by performing sol-gel hydrolysis and condensation on an organic-inorganic mixed solution including an organic material and an inorganic material;
forming an organic-inorganic composite layer by coating a surface of the display unit with the organic-inorganic composite coating solution to encapsulate the display unit; and
treating the surface of the organic-inorganic composite layer with plasma of reactive gas to form a hybrid protective film including an inorganic part layer where carbon is removed, an organic part layer where carbon is contained in a predetermined amount, and a gradient part layer disposed between the inorganic part layer and the organic part layer and increasing an amount of carbon as being more contiguous to the organic part layer,
wherein the plasma treatment may be performed until the inorganic part layer is formed inside the hybrid protective film to a predetermined thickness.

17. The method of claim 16, wherein the organic-inorganic mixed solution comprises at least one organosilane represented by Formula 1 below, water, and optionally, at least one silicate ester represented by Formula 2 below:
A¹ₗA²ₘA³ₙSi(OE¹)ₚ(OE²)_{q}(OE³)ᵣ [Formula 1]
Si(OG¹)_{α}(OG²)_{β}(OG³)_{γ}(OG)_{δ} [Formula 2]
wherein, A¹, A², and A³ in Formula 1 are each independently a C₁-C₂₀ alkyl group, a C₁-C₂₀ fluoroalkyl group, a C₆-C₂₀ aryl group, a vinyl group, an acryl group, a methacryl group, or an epoxy group, l, m, and n are each independently 0 or an integer satisfying the equation of 1≦l+m+n≦3, E¹, E², E³ are each independently a C₁-C₁₀ alkyl group, a C₁-C₁₀ fluoroalkyl group, a C₆-C₂₀ aryl group, a C₁-C₂₀ alkyloxyalkyl group, a C₁-C₂₀ fluoroalkyloxyalkyl group, a C₁-C₂₀ alkyloxyaryl group, a C₆-C₂₀ aryloxyalkyl group, or a C₆-C₂₀ aryloxyaryl group, and p, q, and r are each independently 0 or an integer of 1 to 3 satisfying the equation of 1≦p+q+r≦3 and l+m+n+p+q+r=4, and
wherein G¹, G², G³, and G⁴ in Formula 2 are each independently a C₁-C₁₀ alkyl group, a C₁-C₁₀ fluoroalkyl group, a C₁-C₂₀ aryl group, a C₁-C₂₀ alkyloxyalkyl group, a C₁-C₂₀ fluoroalkyloxyalkyl group, a C₁-C₂₀ alkyloxyaryl group, a C₁-C₂₀ aryloxyalkyl group, or a C₆-C₂₀ aryloxyaryl group, and α, β, γ, and δ are each independently 0 or an integer of 1 to 4 satisfying the equation of α+β+γ+δ=4.

18. The method of claim 17, wherein the organic-inorganic mixed solution further comprises at least one oxide precursor, and the oxide precursor comprises at least one other element selected from alkali metal, alkali earth metal, transition metal, post-transition metal, metalloid, boron, and phosphorous, and in addition, the oxide precursor is capable of forming an oxide of the other element and oxygen.

19. The method of claim 16, further comprising:
forming at least one of the organic-inorganic composite layer and the inorganic barrier layer including an inorganic material, on top of the hybrid protective film.

20. The method of claim 16, further comprising:
forming at least one of the organic-inorganic composite layer and the inorganic barrier layer including an inorganic material, between the display unit and the hybrid protective film.
